(19) United States
(12) Patent Application Publication
(10) Pub. No.: US 2020/0379346 A1
(43) Pub. Date: Dec. 3, 2020

(54) PHOTOSENSITIVE COLORING COMPOSITION, CURED FILM, METHOD FOR FORMING PATTERN, COLOR FILTER, SOLID-STATE IMAGING ELEMENT, AND IMAGE DISPLAY DEVICE

(71) Applicant: FUJIFILM Corporation, Tokyo (JP)

(72) Inventor: Keiji Yamamoto, Haibara-gun (JP)

(73) Assignee: FUJIFILM Corporation, Tokyo (JP)

(21) Appl. No.: 16/994,994

(22) Filed: Aug. 17, 2020

Related U.S. Application Data
(63) Continuation of application No. PCT/JP2019/007156, filed on Feb. 26, 2019.

(30) Foreign Application Priority Data
Mar. 5, 2018 (JP) 2018-038621

(51) Int. Cl. G03F 7/00; C08F 20/28; C08F 2/50; C08K 5/33; C08K 5/132; G03F 7/09; G03F 7/20

(52) U.S. Cl. CPC G03F 7/0007; C08F 20/28; C08F 2/50; C08K 5/33; C08L 2203/20; G03F 7/09; G03F 7/2002; G03F 7/2024; C08L 2203/16; C08K 5/132

(57) ABSTRACT

Provided are a photosensitive coloring composition including a coloring material, a photopolymerization initiator A1 having a light absorption coefficient of 1.0×10⁴ mL/g·cm or more at a wavelength of 365 nm in methanol, a photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol, and a polymerizable monomer, in which a content of the polymerizable monomer in a total solid content of the photosensitive coloring composition is 15% by mass or more; a cured film, a method for forming a pattern, a color filter, a solid-state imaging element, and an image display device.

### CROSS-REFERENCE TO RELATED APPLICATIONS

This application is a Continuation of PCT International Application No. PCT/JP2019/007156 filed on Feb. 26, 2019, which claims priority under 35 U.S.C § 119(a) to Japanese Patent Application No. 2018-038621 filed on Mar. 5, 2018. Each of the above application(s) is hereby expressly incorporated by reference, in its entirety, into the present application.

### BACKGROUND OF THE INVENTION

### 1. Field of the Invention

The present invention relates to a photosensitive coloring composition. More specifically, the present invention relates to a photosensitive coloring composition used for forming a color pixel or the like of a color filter. The present invention further relates to a cured film, a method for forming a pattern, a color filter, a solid-state imaging element, and an image display device, each of which is formed of the photosensitive coloring composition.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

The color filter has been produced using a photosensitive coloring composition including a coloring material, a polymerizable monomer, and a photopolymerization initiator. For example, WO2016/158114A describes producing a color filter using a photosensitive coloring composition formed of, as a photopolymerization initiator, an oxime ester-based photopolymerization initiator including a fluorine atom.

In addition, in recent years, the use of an organic electroluminescence (organic EL) as a light-emitting source in an image display device or the use of an organic material as a photoelectric conversion film in an image sensor has been studied. These members usually have low heat resistance. Therefore, producing the color filter at a low temperature has been studied. For example, JP2015-041058A describes a method for producing a color filter, the method including, in this order: a step (i) of forming a layer on a substrate using a photosensitive coloring composition; a step (ii) of exposing a photosensitive coloring composition layer with light having a wavelength of more than 350 nm and 380 nm or less; a step (iii) of performing a alkali development on the photosensitive coloring composition layer; and a step (iv) of exposing the photosensitive coloring composition layer with light having a wavelength of 254 to 350 nm, in which the photosensitive coloring composition contains a polymerization initiator (a) having a light absorption coefficient of 1.0×10³ mL/g·cm or more at a wavelength of 365 nm in methanol, a polymerization initiator (b) having a light absorption coefficient of 1.0×10² mL/g·cm or less at a wavelength of 365 nm in methanol and having a light absorption coefficient of 1.0×10³ mL/g·cm or more at a wavelength of 254 nm in methanol, a compound (c) which has an unsaturated double bond, an alkali-soluble resin (d), and a coloring material (e), and in the total solid content of the photosensitive coloring composition, the content of the polymerization initiator (a) is 1.5% to 10% by mass and the content of the polymerization initiator (b) is 1.5% to 7.5% by mass.

### SUMMARY OF THE INVENTION

As described above, in recent years, producing the color filter at lower temperature has been studied.

In addition, regarding a pattern of a cured film used for the color filter, increasing the film thickness also has been studied. However, in a case of producing the pattern of a cured film, which has a large thickness at a low temperature, it is difficult to achieve all of solvent resistance, adhesiveness, and rectangularity.

Therefore, an object of the present invention is to provide a photosensitive coloring composition capable of forming a pattern having excellent solvent resistance, adhesiveness, and rectangularity. Another object of the present invention is to provide a cured film, a method for forming a pattern, a color filter, a solid-state imaging element, and an image display device.

As a result of intensive studies, the present inventor has found that the above object can be achieved by using a photosensitive coloring composition described later, thereby leading to completion of the present invention. That is, the present invention is as follows.

<1> A photosensitive coloring composition comprising:

a coloring material;

a photopolymerization initiator A1 having a light absorption coefficient of 1.0×10⁴ mL/g·cm or more at a wavelength of 365 nm in methanol;

a photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol; and

a polymerizable monomer,

in which a content of the polymerizable monomer in a total solid content of the photosensitive coloring composition is 15% by mass or more.

<2> The photosensitive coloring composition according to <1>,

in which the photopolymerization initiator A1 is an oxime compound including a fluorine atom.

<3> The photosensitive coloring composition according to <1> or <2>,

in which the photopolymerization initiator A2 is a hydroxyalkylphenone compound.

<4> The photosensitive coloring composition according to <1> or <2>,

in which the photopolymerization initiator A2 is a compound represented by Formula (A2-1),

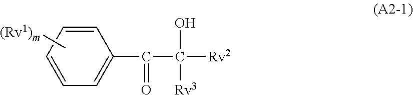

in the formula, Rv¹ represents a substituent, Rv² and Rv³ each independently represent a hydrogen atom or a substituent, Rv² and Rv³ may be bonded to each other to form a ring, and m represents an integer of 0 to 5.

<5> The photosensitive coloring composition according to any one of <1> to <4>,

in which the photosensitive coloring composition contains 50 to 200 parts by mass of the photopolymerization initiator A2 with respect to 100 parts by mass of the photopolymerization initiator A1.

<6> The photosensitive coloring composition according to any one of <1> to <5>,

in which a total content of the photopolymerization initiator A1 and the photopolymerization initiator A2 in the total solid content of the photosensitive coloring composition is 5% to 15% by mass.

<7> The photosensitive coloring composition according to any one of <1> to <6>,

in which the polymerizable monomer is a compound including three or more ethylenically unsaturated groups.

<8> The photosensitive coloring composition according to any one of <1> to <7>,

in which the polymerizable monomer is a compound including an ethylenically unsaturated group and an alkyleneoxy group.

<9> The photosensitive coloring composition according to any one of <1> to <8>,

in which the photosensitive coloring composition contains 170 to 345 parts by mass of the polymerizable monomer with respect to 100 parts by mass of a total amount of the photopolymerization initiator A1 and the photopolymerization initiator A2.

<10> The photosensitive coloring composition according to any one of <1> to <9>,

in which a content of the polymerizable monomer the total solid content of the photosensitive coloring composition is 17.5% to 27.5% by mass.

<11> The photosensitive coloring composition according to any one of <1> to <10>, further comprising:

a resin.

<12> The photosensitive coloring composition according to <11>,

in which a content of the resin is 50 to 170 parts by mass with respect to 100 parts by mass of the polymerizable monomer.

<13> A cured film obtained by curing the photosensitive coloring composition according to any one of <1> to <12>.

<14> A method for forming a pattern, the method comprising:

a step of forming a photosensitive coloring composition layer on a support using the photosensitive coloring composition according to any one of <1> to <12>;

a step of irradiating the photosensitive coloring composition layer with a light having a wavelength of more than 350 nm and 380 nm or less to patternwise expose the photosensitive coloring composition layer;

a step of developing the photosensitive coloring composition layer after the exposure; and

a step of irradiating the photosensitive coloring composition layer after the development with a light having a wavelength of 254 to 350 nm to expose the photosensitive coloring composition layer after the development.

<15> A color filter comprising:

the cured film according to <13>.

<16> A solid-state imaging element comprising:

the cured film according to <13>.

<17> An image display device comprising:

the cured film according to <13>.

According to the present invention, it is possible to provide a photosensitive coloring composition capable of forming a pattern having excellent solvent resistance, adhesiveness, and rectangularity. It is also possible to provide a cured film, a method for forming a pattern, a color filter, a solid-state imaging element, and an image display device.

### DESCRIPTION OF THE PREFERRED EMBODIMENTS

Hereinafter, the contents of the present invention will be described in detail.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure generally include actinic rays or radiation such as a bright line spectrum of a mercury lamp, far ultraviolet rays typified by an excimer laser, extreme ultraviolet rays (EUV light), X-rays, or electron beams.

In the present specification, a numerical range expressed using “to” means a range that includes the preceding and succeeding numerical values of “to” as the lower limit value and the upper limit value, respectively.

In the present specification, the total solid content refers to a total mass of components other than a solvent from all the components of a composition.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, the term “step” is not only an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

<Photosensitive Coloring Composition>

The photosensitive coloring composition according to an embodiment of the present invention includes:

a coloring material;

a photopolymerization initiator A1 having a light absorption coefficient of 1.0×10⁴ mL/g·cm or more at a wavelength of 365 nm in methanol;

a photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol; and

a polymerizable monomer,

in which a content of the polymerizable monomer in a total solid content of the photosensitive coloring composition is 15% by mass or more.

By using the photosensitive coloring composition according to the embodiment of the present invention, it is possible to form a pattern having excellent solvent resistance, adhesiveness, and rectangularity. That is, since the photopolymerization initiator A1 and the photopolymerization initiator A2 are used in combination as a photopolymerization initiator in the photosensitive coloring composition according to the embodiment of the present invention, it is possible to expose and cure the photosensitive coloring composition in two stages before development and after development. Furthermore, since the photosensitive coloring composition according to the embodiment of the present invention contains 15% by mass or more of the polymerizable monomer in the total solid content of the photosensitive coloring composition, and includes the photopolymerization initiator A1, it is possible to firmly cure the photosensitive coloring composition to the bottom in the first exposure (exposure before development). Therefore, it is possible to form a pattern having excellent adhesiveness and rectangularity. Furthermore, since the entire photosensitive coloring composition can be cured almost completely in the next exposure (exposure after development), it is possible to form a pattern having excellent solvent resistance. For example, in a case where a pattern (pixel) of a cured film of respective color is sequentially formed using photosensitive coloring compositions having a plurality of colors to produce a color filter having pixels of a plurality of colors, pixels formed in the previous step are also exposed to a developer in a case of forming pixels of second and subsequent colors. However, since a pattern having excellent solvent resistance can be formed by using the photosensitive coloring composition according to the embodiment of the present invention, it is possible to suppress color loss from the pixels formed before the case of forming pixels of second and subsequent colors.

In addition, according to the photosensitive coloring composition according to the embodiment of the present invention, it is possible to form a pattern having excellent solvent resistance, adhesiveness, and rectangularity even in a case of forming a pattern by, for example, a low-temperature process of 120° C. or lower. Therefore, the photosensitive coloring composition according to the embodiment of the present invention is particularly effective in a case of forming a pattern by a low-temperature process.

Hereinafter, the photosensitive coloring composition according to the embodiment of the present invention will be described in detail.

<<Coloring Material>>

The photosensitive coloring composition according to the embodiment of the present invention contains a coloring material. Examples of the coloring material include chromatic coloring materials such as a red coloring material, a green coloring material, a yellow coloring material, a green coloring material, a purple coloring material, and an orange coloring material. In the present invention, the coloring material may be a pigment or a dye. The coloring material may be used in combination of the pigment and the dye. The coloring material used in the present invention preferably includes the pigment. In addition, the content of the pigment in the coloring material is preferably 50% by mass or more, more preferably 70% by mass or more, still more preferably 80% by mass or more, and particularly preferably 90% by mass or more. In addition, the coloring material may be only constituted with the pigment.

As the pigment, an organic pigment is preferable. Examples of the organic pigment include the following pigments:

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C. I. Pigment Green 7, 10, 36, 37, 58, 59, 62, and 63 (all of which are green pigments);

C. I. Pigment Violet 1, 19, 23, 27, 32, 37, and 42 (all of which are violet pigments);

and

C. I. Pigment Blue 1, 2, 15, 15:1, 15:2, 15:3, 15:4, 15:6, 16, 22, 60, 64, 66, 79, and 80 (all of which are blue pigments).

Among these organic pigments, one kind thereof may be used alone, or two or more kinds thereof may be used in combination.

In addition, as the yellow pigment, a metal azo pigment which includes at least one kind of an anion selected from an azo compound represented by Formula (I) or an azo compound having a tautomeric structure of the azo compound represented by Formula (I), two or more kinds of metal ions, and a melamine compound can be used.

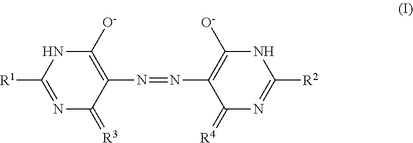

In the formula, R¹ and R² each independently represent OH or NR⁵R⁶, R³ and R⁴ each independently represent ═O or ═NR⁷, and R⁵ to R⁷ each independently represent a hydrogen atom or an alkyl group. The alkyl group represented by R⁵ to R⁷ preferably has 1 to 10 carbon atoms, more preferably has 1 to 6 carbon atoms, and still more preferably has 1 to 4 carbon atoms. The alkyl group may be any of linear, branched, and cyclic forms, and is preferably linear or branched and more preferably linear. The alkyl group may have a substituent. The substituent is preferably a halogen atom, a hydroxyl group, an alkoxy group, a cyano group, or an amino group.

In Formula (I), it is preferable that R¹ and R² are OH. In addition, it is preferable that R³ and R⁴ are ═O.

It is preferable that the melamine compound in the metal azo pigment is a compound represented by Formula (II).

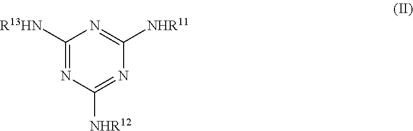

In the formula, R¹¹ to R¹³ each independently represent a hydrogen atom or an alkyl group. The alkyl group preferably has 1 to 10 carbon atoms, more preferably has 1 to 6 carbon atoms, and still more preferably has 1 to 4 carbon atoms. The alkyl group may be any of linear, branched, and cyclic forms, and is preferably linear or branched and more preferably linear. The alkyl group may have a substituent. The substituent is preferably a hydroxyl group. It is preferable that at least one of R¹¹ to R¹³ is a hydrogen atom, and it is more preferable that all of R¹¹ to R¹³ are hydrogen atoms.

It is preferable that the metal azo pigment is a metal azo pigment according to an aspect including the at least one kind of an anion selected from an azo compound represented by Formula (I) or an azo compound having a tautomeric structure of the azo compound represented by Formula (I), metal ions including at least Zn²⁺ and Cu²⁺, and a melamine compound. In this aspect, Zn²⁺ and Cu²⁺ are contained preferably in the total amount of 95% to 100% by mole, more preferably 98% to 100% by mole, still more preferably 99.9% to 100% by mole, and particularly preferably 100% with respect to 1 mol of all the metal ions of the metal azo pigment. In addition, a molar ratio of Zn²⁺ to Cu²⁺ in the metal azo pigment is preferably Zn²⁺:Cu²⁺=199:1 to 1:15, more preferably 19:1 to 1:1, and still more preferably 9:1 to 2:1. In addition, in this aspect, the metal azo pigment may further include a divalent or trivalent metal ion (hereinafter, also referred to as a metal ion Me1) in addition to Zn²⁺ and Cu²⁺. Examples of the metal ion Me1 include Ni²⁺, Al³⁺, Fe²⁺, Fe³⁺, Co²⁺, Co³⁺, La³⁺, Ce³⁺, Pr³⁺, Nd²⁺, Nd³⁺, Sm²⁺, Sm³⁺, Eu²⁺, EU³⁺, Gd³⁺, Tb³⁺, Dy³⁺, Ho³⁺, Yb²⁺, Yb³⁺, Er³⁺, Tm³⁺, Mg²⁺, Ca²⁺, Sr²⁺, Mn²⁺, Y³⁺, Sc³⁺, Ti²⁺, Ti³⁺, Nb³⁺, Mo²⁺, Mo³⁺, V²⁺, V³⁺, Zr²⁺, Zr³⁺, Cd²⁺, Cr³⁺, Pb²⁺, and Ba²⁺. Among these, at least one selected from Al³⁺, Fe²⁺, Fe³⁺, Co²⁺, Co³⁺, La³⁺, Ce³⁺, Pr³⁺, Nd³⁺, Sm³⁺, Eu³⁺, Gd³⁺, Tb³⁺, Dy³⁺, Ho³⁺, Yb³⁺, Er³⁺, Tm³⁺, Mg²⁺, Ca²⁺, Sr²⁺, Mn²⁺, and Y³⁺ is preferable, at least one selected from Al³⁺, Fe²⁺, Fe³⁺, Co²⁺, Co³⁺, La³⁺, Ce³⁺, Pr³⁺, Nd³⁺, Sm³⁺, Tb³⁺, Ho³⁺, and Sr²⁺ is still more preferable, and at least one selected from Al³⁺, Fe²⁺, Fe³⁺, Co²⁺, or Co³⁺ is particularly preferable. The content of the metal ion Me1 is preferably 5% by mole or less, more preferably 2% by mole or less, and still more preferably 0.1% by mole or less based on 1 mol of all the metal ions of the metal azo pigment.

The details of the metal azo pigment can be found in paragraph Nos. 0011 to 0062 and 0137 to 0276 of JP2017-171912A, paragraph Nos. 0010 to 0062 and 0138 to 0295 of JP2017-171913A, paragraph Nos. 0011 to 0062 and 0139 to 0190 of JP2017-171914A, and paragraph Nos. 0010 to 0065 and 0142 to 0222 of JP2017-171915A, the contents of which are incorporated herein by reference.

In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

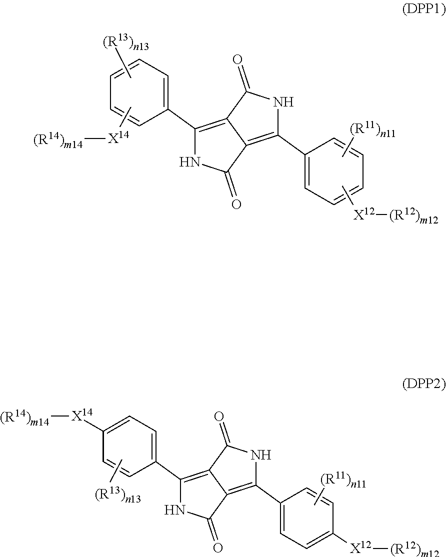

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Preferred specific examples of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A.

In addition, an aluminum phthalocyanine compound having a phosphorus atom can also be used as the blue pigment. Specific examples thereof include the compounds described in paragraphs 0022 to 0030 of JP2012-247591A and paragraph 0047 of JP2011-157478A.

The dye is not particularly limited and a known dye can be used. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethane-based dye. In addition, the thiazole compound described in JP2012-158649A, the azo compound described in JP2011-184493A, or the azo compound described in JP2011-145540A can also be preferably used. In addition, as yellow dyes, the quinophthalone compounds described in paragraph Nos. 0011 to 0034 of JP2013-054339A, the quinophthalone compounds described in paragraph Nos. 0013 to 0058 of JP2014-026228A, or the like can be used.

In addition, in the present invention, a coloring agent multimer can be used as the coloring material. The coloring agent multimer is preferably a dye which is used after being dissolved in a solvent, but the coloring agent multimer may form a particle. In a case where the coloring agent multimer is the particle, it is usually used in a state of being dispersed in a solvent. The coloring agent multimer in the particle state can be obtained by, for example, emulsion polymerization, and specific examples thereof include the compounds and production methods described in JP2015-214682A. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structures or different coloring agent structures.

The weight-average molecular weight (Mw) of the coloring agent multimer is preferably 2,000 to 50,000. The lower limit is more preferably 3,000 or more and still more preferably 6,000 or more. The upper limit is more preferably 30,000 or less and still more preferably 20,000 or less.

Examples of the coloring agent structure included in the coloring agent multimer include a structure derived from a coloring agent compound having absorption in a visible range (preferably in a wavelength range of 400 to 700 nm and more preferably in a wavelength range of 400 to 650 nm). Examples thereof include a triaryl methane coloring agent structure, a xanthene coloring agent structure, an anthraquinone coloring agent structure, a cyanine coloring agent structure, a squarylium coloring agent structure, a quinophthalone coloring agent structure, a phthalocyanine coloring agent structure, a subphthalocyanine coloring agent structure, an azo coloring agent structure, a pyrazolotriazole coloring agent structure, a dipyromethane coloring agent structure, an isoindoline coloring agent structure, a thiazole coloring agent structure, a benzimidazolone coloring agent structure, a perinone coloring agent structure, a diketopyrrolopyrrole coloring agent structure, a diimmonium coloring agent structure, a naphthalocyanine coloring agent structure, a rylene coloring agent structure, a dibenzofuranone coloring agent structure, a merocyanine coloring agent structure, a croconium coloring agent structure, and an oxonol coloring agent structure.

The coloring agent multimer is preferably a coloring agent multimer having a repeating unit represented by Formula (A), a coloring agent multimer having a repeating unit represented by Formula (B), a coloring agent multimer having a repeating unit represented by Formula (C), or a coloring agent multimer represented by Formula (D), and more preferably a coloring agent multimer having a repeating unit represented by Formula (A) or a coloring agent multimer represented by Formula (D).

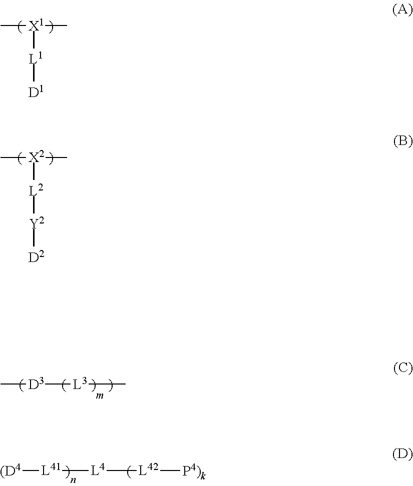

In Formula (A), X¹ represents a main chain of a repeating unit, L¹ represents a single bond or a divalent linking group, and D¹ represents a coloring agent structure. With regard to the details of Formula (A), reference can be made to paragraphs 0138 to 0152 of JP2013-029760A, the contents of which are incorporated herein by reference.

In Formula (B), X² represents a main chain of a repeating unit, L² represents a single bond or a divalent linking group, D² represents a coloring agent structure having a group which can be bonded to Y² by an ion bond or a coordinate bond, and Y² represents a group which can be bonded to D² by an ion bond or a coordinate bond. With regard to the details of Formula (B), reference can be made to paragraphs 0156 to 0161 of JP2013-029760A, the contents of which are incorporated herein by reference.

In Formula (C), L³ represents a single bond or a divalent linking group, D³ represents a coloring agent structure, and m represents 0 or 1. With regard to the details of Formula (C), reference can be made to paragraphs 0165 to 0167 of JP2013-029760A, the contents of which are incorporated herein by reference.

In Formula (D), L⁴ represents an (n+k)-valent linking group, L⁴¹ and L⁴² each independently represent a single bond or a divalent linking group, D⁴ represents a coloring agent structure, and P⁴ represents a substituent; n represents 2 to 15, k represents 0 to 13, and n+k is 2 to 15. In a case where n is 2 or more, a plurality of D⁴'s may be the same as or different from each other. In a case where k is 2 or more, a plurality of P⁴'s may be the same as or different from each other. Examples of the (n+k)-valent linking group represented by L⁴ include the linking group described in paragraph Nos. 0071 and 0072 of JP2008-222950A, and the linking group described in paragraph No. 0176 of JP2013-029760A. Examples of the substituent represented by P⁴ include an acid group and a polymerizable group. Examples of the polymerizable group include an ethylenically unsaturated group, an epoxy group, an oxazoline group, and a methylol group. Examples of the ethylenically unsaturated group include a vinyl group, a (meth)allyl group, and a (meth)acryloyl group. Examples of the acid group include a carboxyl group, a sulfonic acid group, and a phosphoric acid group. The substituent represented by P⁴ may be a monovalent polymer chain having a repeating unit. The monovalent polymer chain having a repeating unit is preferably a monovalent polymer chain having a repeating unit derived from a vinyl compound.

As the coloring agent multimer, the compounds described in JP2011-213925A, JP2013-041097A, JP2015-028144A, JP2015-030742A, WO2016/031442A, or the like can also be used.

The content of the coloring material in the total solid content of the photosensitive coloring composition is preferably 5% to 70% by mass. The lower limit is preferably 10% by mass or more, more preferably 15% by mass or more, and still more preferably 20% by mass or more. The upper limit is preferably 60% by mass or less, still more preferably 55% by mass or less, and even more preferably 50% by mass or less.

<<Photopolymerization Initiator>>

The photosensitive coloring composition according to the embodiment of the present invention contains a photopolymerization initiator. Examples of the photopolymerization initiator include halogenated hydrocarbon derivatives (such as a compound having a triazine skeleton and a compound having an oxadiazole skeleton), acylphosphine compounds such as acylphosphine oxide, a hexaaryl biimidazole compound, oxime compounds such as an oxime derivative, an organic peroxide, a thio compound, a ketone compound, an aromatic onium salt, a ketoxime ether compound, an aminoalkylphenone compound, a hydroxyalkylphenone compound, and a phenylglyoxylate compound. With regard to the specific examples of the photopolymerization initiator, reference can be made to paragraph Nos. 0265 to 0268 of JP2013-029760A, the contents of which are incorporated herein by reference.

Examples of the phenylglyoxylate compound include phenylglyoxylic acid methyl ester. Examples of a commercially available product of the phenylglyoxylate compound include DAROCUR-MBF (manufactured by BASF).

Examples of the aminoalkylphenone compound include the aminoalkylphenone compound described in JP1988-291969A (JP-H10-291969A). In addition, as the aminoalkylphenone compound, IRGACURE-907, IRGACURE-369, and IRGACURE-379 (all of which are manufactured by BASF) can be used.

Examples of the acylphosphine compound include the acylphosphine compound described in JP4225898B. Specific examples thereof include bis(2,4,6-trimethylbenzoyl)-phenylphosphine oxide. As the acylphosphine compound, IRGACURE-819 and DAROCUR-TPO (both of which are manufactured by BASF) can be used.

Examples of the hydroxyalkylphenone compound include a compound represented by Formula (A2-1).

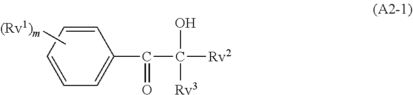

In the formula, Rv¹ represents a substituent, Rv² and Rv³ each independently represent a hydrogen atom or a substituent, Rv² and Rv³ may be bonded to each other to form a ring, and m represents an integer of 0 to 5.

Examples of the substituent represented by Rv¹ include an alkyl group (preferably an alkyl group having 1 to 10 carbon atoms) and an alkoxy group (preferably an alkoxy group having 1 to 10 carbon atoms). The alkyl group and alkoxy group is preferably linear or branched, and more preferably linear. The alkyl group and alkoxy group represented by Rv¹ may be unsubstituted or may have a substituent. Examples of the substituent include a hydroxyl group and a group having a hydroxyacetophenone structure. Examples of the group having a hydroxyacetophenone structure include a group of a structure in which, in Formula (A2-1), one hydrogen atom is removed from the benzene ring bonded with Rv¹ or from Rv¹.

Rv² and Rv³ each independently represent a hydrogen atom or a substituent. As the substituent, an alkyl group (preferably an alkyl group having 1 to 10 carbon atoms) is preferable. In addition, Rv² and Rv³ may be bonded to each other to form a ring (preferably a ring having 4 to 8 carbon atoms and more preferably an aliphatic ring having 4 to 8 carbon atoms). The alkyl group is preferably linear or branched, and more preferably linear.

Specific examples of the compound represented by Formula (A2-1) include the following compounds.

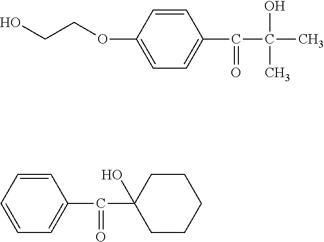 [SMILES: CC(C)(O)C(=O)c1ccc(OCCO)cc1 ; O=C(c1ccccc1)C1(O)CCCCC1]

Examples of the hydroxyalkylphenone compound include IRGACURE-184, DAROCUR-1173, IRGACURE-500, IRGACURE-2959, and IRGACURE-127 (trade names, all of which is manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, and the compounds described in WO2017/051680A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. Examples of a commercially available product of the oxime compound include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADKEA Corporation; photopolymerization initiator 2 described in JP2012-014052A). In addition, as the oxime compound, it is also preferable to use a compound having no coloring property or a compound having high transparency and hardly causing discoloration of other components. Examples of a commercially available product of the oxime compound include ADEKA ARKLS NCI-730, NCI-831, and NCI-930 (all of which are manufactured by ADEKA Corporation).

The oxime compound is preferably an oxime compound having a fluorine atom. The oxime compound including a fluorine atom preferably has a group including a fluorine atom. The group including a fluorine atom is preferably an alkyl group having a fluorine atom (hereinafter, also referred to as a fluorine-containing alkyl group) or a group including an alkyl group having a fluorine atom (hereinafter, also referred to as a fluorine-containing group). As the fluorine-containing group, at least one group selected from —OR^{F1}, —SR^{F1}, —COR^{F1}, —COOR^{F1}, —OCOR^{F1}, —NR^{F1}RF², —NHCOR^{F1}, —CONR^{F1}R^{F2}, —NHCONR^{F1}R^{F2}, —NHCOOR^{F1}, —SO₂R^{F1}, —SO₂OR^{F1}, and —NHSO₂R^{F1} preferable. R^{F1} represents a fluorine-containing alkyl group, and R^{F2} represents a hydrogen atom, an alkyl group, a fluorine-containing alkyl group, an aryl group, or a heterocyclic group. The fluorine-containing group is preferably —OR^{F1}.

The alkyl group and fluorine-containing alkyl group preferably has 1 to 20 carbon atoms, more preferably has 1 to 15 carbon atoms, still more preferably 1 to 10 carbon atoms, and particularly preferably has 1 to 4 carbon atoms. The alkyl group and fluorine-containing alkyl group may be any of linear, branched, and cyclic forms, and are preferably linear or branched. The substitution rate of fluorine atoms in the fluorine-containing alkyl group is preferably 40% to 100%, more preferably 50% to 100%, and still more preferably 60% to 100%. The substitution rate of fluorine atoms refers to a ratio (%) of the number substituted with fluorine atoms to the total number of hydrogen atoms in the alkyl group.

The aryl group preferably has 6 to 20 carbon atoms, more preferably has 6 to 15 carbon atoms, and still more preferably has 6 to 10 carbon atoms.

The heterocyclic group is preferably a 5-membered ring or a 6-membered ring. The heterocyclic group may be monocyclic or a fused ring. The fused number is preferably 2 to 8, more preferably 2 to 6, still more preferably 3 to 5, and particularly preferably 3 or 4. The number of carbon atoms constituting the heterocyclic group is preferably 3 to 40, more preferably 3 to 30, and more preferably 3 to 20. The number of heteroatoms constituting the heterocyclic group is preferably 1 to 3. The heteroatom constituting the heterocyclic group is preferably a nitrogen atom, an oxygen atom, or a sulfur atom, and more preferably a nitrogen atom.

The group including a fluorine atom preferably has a terminal structure represented by Formula (1) or (2). * in the formula represents a linking hand.

*—CHF₂ (1)

*—CF₃ (2)

The total number of fluorine atoms in the oxime compound including a fluorine atom is preferably 3 or more and more preferably 4 to 10.

The oxime compound including a fluorine atom is preferably a compound represented by Formula (OX-1).

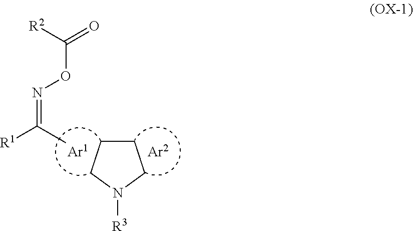

In Formula (OX-1), Ar¹ and Ar² each independently represent an aromatic hydrocarbon ring which may have a substituent, R¹ represents an aryl group having a group including a fluorine atom, and R² and R³ each independently represent an alkyl group or an aryl group.

Ar¹ and Ar² each independently represent an aromatic hydrocarbon ring which may have a substituent. The aromatic hydrocarbon ring may be monocyclic or a fused ring. The number of carbon atoms constituting the ring of the aromatic hydrocarbon ring is preferably 6 to 20, more preferably 6 to 15, and particularly preferably 6 to 10. The aromatic hydrocarbon ring is preferably a benzene ring or a naphthalene ring. Among these, it is preferable that at least one of Ar¹ or Ar² is a benzene ring, and it is more preferable that Ar¹ is a benzene ring. Ar² is preferably a benzene ring or a naphthalene ring and more preferably a naphthalene ring.

Example of the substituent which may be included in Ar¹ and Ar² include an alkyl group, an aryl group, a heterocyclic group, a nitro group, a cyano group, a halogen atom, —OR^{X1}, —SR^{X1}, —COR^{X1}, —COR^{X1}, —OCOR^{X1}, —NR^{X1}R^{X2}, —NHCOR^{X1}, —CONR^{X1}R^{X2}, —NHCONR^{X1}R^{X2}, —NHCOOR^{X1}, —SO₂R^{X1}, —SO₂OR^{X1}, and —NHSO₂R^{X1}, R^{X1} and R^{X2} each independently represent a hydrogen atom, an alkyl group, an aryl group, or a heterocyclic group.

Examples of the halogen atom include a fluorine atom, a chlorine atom, a bromine atom, and an iodine atom, and a fluorine atom is preferable. The number of carbon atoms of the alkyl group as the substituent and the alkyl group represented by R^{X1} and R^{X2} is preferably 1 to 30. The alkyl group may be any of linear, branched, and cyclic forms, and is preferably linear or branched. In the alkyl group, a part or all of the hydrogen atoms may be substituted with halogen atoms (preferably fluorine atoms). In addition, in the alkyl group, a part or all of the hydrogen atoms may be substituted with the above-described substituents. The number of carbon atoms of the aryl group as the substituent and the aryl group represented by R^{X1} and R^{X2} is preferably 6 to 20, more preferably 6 to 15, and still more preferably 6 to 10. The aryl group may be monocyclic or a fused ring. In addition, in the aryl group, a part or all of the hydrogen atoms may be substituted with the above-described substituents. The heterocyclic group as the substituent and the heterocyclic group represented by R^{X1} and R^{X2} are preferably a 5-membered ring or a 6-membered ring. The heterocyclic group may be monocyclic or a fused ring. The number of carbon atoms constituting the heterocyclic group is preferably 3 to 30, more preferably 3 to 18, and more preferably 3 to 12. The number of heteroatoms constituting the heterocyclic group is preferably 1 to 3. The heteroatom constituting the heterocyclic group is preferably a nitrogen atom, an oxygen atom, or a sulfur atom. In addition, in the heterocyclic group, a part or all of the hydrogen atoms may be substituted with the above-described substituents.

The aromatic hydrocarbon ring represented by Ar¹ is preferably unsubstituted. The aromatic hydrocarbon ring represented by Ar² may be unsubstituted or may have a substituent. It is preferable to have a substituent. As the substituent, —COR^{X1} is preferable. R^{X1} is preferably an alkyl group, an aryl group, or a heterocyclic group, and more preferably an aryl group. The aryl group may have a substituent or may be unsubstituted. Examples of the substituent include an alkyl group having 1 to 10 carbon atoms.

R¹ represents an aryl group having a group including a fluorine atom. The aryl group preferably has 6 to 20 carbon atoms, more preferably has 6 to 15 carbon atoms, and still more preferably has 6 to 10 carbon atoms. The group including a fluorine atom is preferably an alkyl group having a fluorine atom (fluorine-containing alkyl group) or a group including an alkyl group having a fluorine atom (fluorine-containing group). The group including a fluorine atom has the same range as described above, and the preferred range is also the same.

R² represents an alkyl group or an aryl group, and is preferably an alkyl group. The alkyl group and aryl group may be unsubstituted or may have a substituent. Examples of the substituent include the substituents described as the substituent which may be included in Ar¹ and Ar². The alkyl group preferably has 1 to 20 carbon atoms, more preferably has 1 to 15 carbon atoms, still more preferably has 1 to 10 carbon atoms, and particularly preferably has 1 to 4 carbon atoms. The alkyl group may be any of linear, branched, and cyclic forms, and is preferably linear or branched. The aryl group preferably has 6 to 20 carbon atoms, more preferably has 6 to 15 carbon atoms, and still more preferably has 6 to 10 carbon atoms.

R³ represents an alkyl group or an aryl group, and is preferably an alkyl group. The alkyl group and aryl group may be unsubstituted or may have a substituent. Examples of the substituent include the substituents described as the substituent which may be included in Ar¹ and Ar². The alkyl group represented by R³ preferably has 1 to 20 carbon atoms, more preferably has 1 to 15 carbon atoms, and still more preferably has 1 to 10 carbon atoms. The alkyl group may be any of linear, branched, and cyclic forms, and is preferably linear or branched. The aryl group represented by R³ preferably has 6 to 20 carbon atoms, more preferably has 6 to 15 carbon atoms, and still more preferably has 6 to 10 carbon atoms.

Specific examples of the oxime compound having a fluorine atom include the compounds described in JP2010-262028A, the compounds 24, and 36 to 40 described in JP2014-500852A, and the compound (C-3) described in JP2013-164471A.

In addition, as the oxime compound, an oxime compound having a fluorene ring can also be used. Specific examples of the oxime compound having a fluorene ring include the compounds described in JP2014-137466A. The contents of the publications are incorporated herein by reference.

In addition, as the oxime compound, an oxime compound having a benzofuran skeleton can also be used. Specific examples thereof include the compounds OE-01 to OE-75 described in WO2015/036910A.

In addition, as the oxime compound, an oxime compound having a skeleton in which at least one benzene ring of a carbazole ring is a naphthalene ring can also be used. Specific examples of such an oxime compound include the compounds described in WO2013/083505A.

In addition, as the oxime compound, an oxime compound having a nitro group can also be used. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

Specific examples of the oxime compound are shown below, but the present invention is not limited thereto.

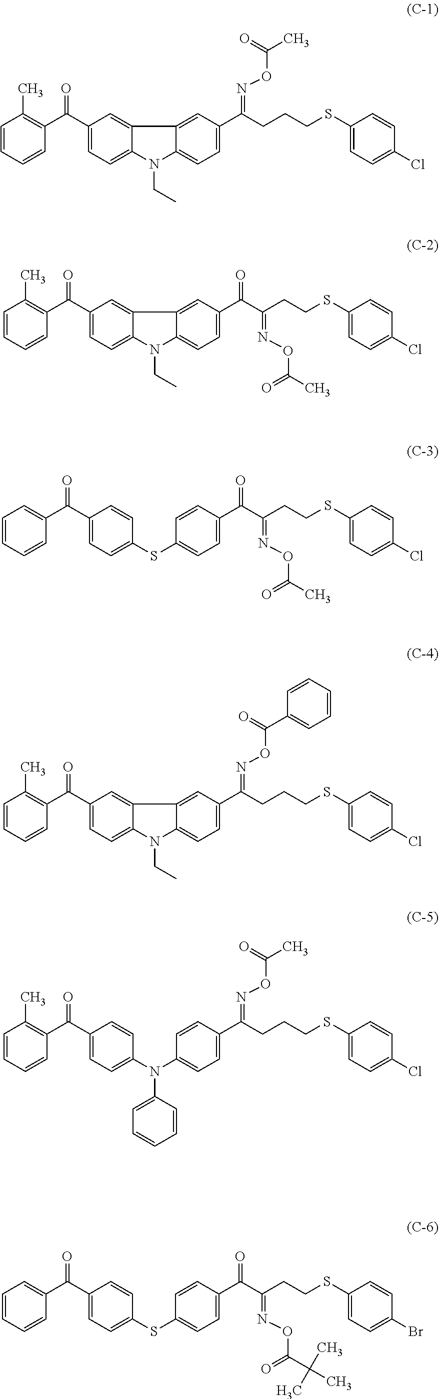 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

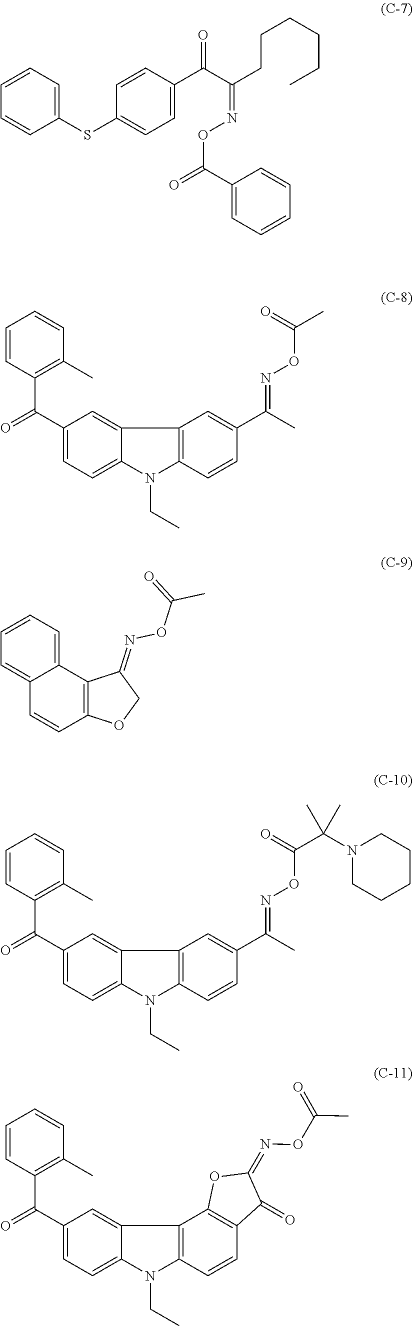 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

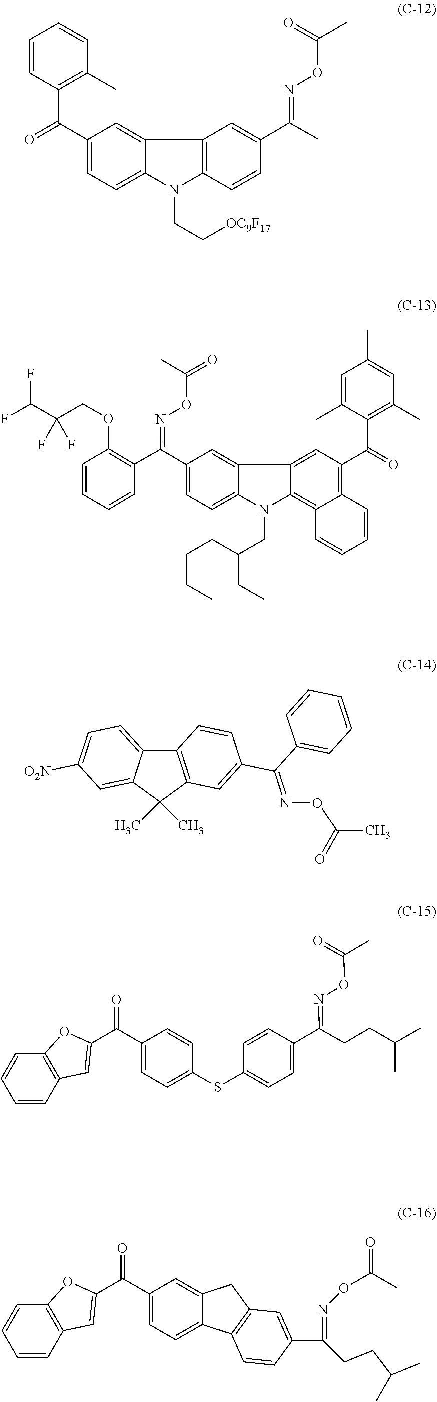

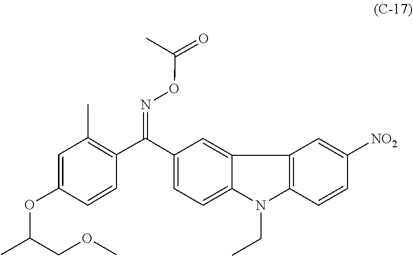 [SMILES: CCn1c2ccc(/C(=N\OC(C)=O)c3ccc(OC(C)COC)cc3C)cc2c2cc([N+](=O)[O-])ccc21]

In the present invention, a bifunctional or trifunctional or higher photopolymerization initiator may be used as the photopolymerization initiator. Specific examples of the bifunctional or trifunctional or higher photopolymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A, the compound (E) and the compound (G) described in JP2013-522445A, Cmpd 1 to 7 described in WO2016/034963A, the oxime ester photoinitiators described in paragraph No. 0007 of JP2017-523465A, the photoinitiators described in paragraph Nos. 0020 to 0033 of JP2017-167399A, and the photopolymerization initiator (A) described in paragraph Nos. 0017 to 0026 of JP2017-151342A.

In the present invention, a photopolymerization initiator A1 (hereinafter, also referred to as a photopolymerization initiator A1) having a light absorption coefficient of 1.0×10⁴ mL/g·cm or more at a wavelength of 365 nm in methanol, and a photopolymerization initiator A2 (hereinafter, also referred to as a photopolymerization initiator A2) having a light absorption coefficient of 1.0×10² mL/g·cm or less at a wavelength of 365 nm in methanol and having a light absorption coefficient of 1.0×10³ mL/g·cm or more at a wavelength of 254 nm in methanol are used in combination as the photopolymerization initiator.

As the photopolymerization initiator A1 and the photopolymerization initiator A2, compounds having the above-described light absorption coefficient can be selected and used from the above-described compounds.

In the present invention, the light absorption coefficient at the above-described wavelength of a photopolymerization initiator is a value measured as follows. That is, the light absorption coefficient is obtained by preparing a measurement solution by dissolving the photopolymerization initiator in methanol and measuring absorbance of the measurement solution. Specifically, the measurement solution is put into a glass cell having a width of 1 cm, absorbance is measured using a UV-Vis-NIR spectrometer (Cary 5000) manufactured by Agilent Technologies Inc., and the light absorption coefficient at a wavelength of 365 nm and a wavelength of 254 nm is obtained by applying the following equation.

$$ɛ = \frac{A}{cl}$$

In the equation, c represents a light absorption coefficient (mL/g·cm), A represents an absorbance, c represents a concentration (g/L) of the photopolymerization initiator, and 1 represents an optical path length (cm).

In the photopolymerization initiator A1, the light absorption coefficient at a wavelength of 365 nm in methanol is 1.0×10⁴ mL/g·cm or more, preferably 1.1×10⁴ mL/g·cm or more, more preferably 1.2×10⁴ to 1.0×10⁵ mL/g·cm, still more preferably 1.3×10⁴ to 5.0×10⁴ mL/g·cm, and particularly preferably 1.5×10⁴ to 3.0×10⁴ mL/g·cm.

In addition, in the photopolymerization initiator A1, the light absorption coefficient at a wavelength of 254 nm in methanol is preferably 1.0×10⁴ to 1.0×10⁵ mL/g·cm, more preferably 1.5×10⁴ to 9.5×10⁴ mL/g·cm, and still more preferably 3.0×10⁴ to 8.0×10⁴ mL/g·cm.

As the photopolymerization initiator A1, an oxime compound, an aminoalkylphenone compound, or an acylphosphine compound is preferable, an oxime compound or an acylphosphine compound is more preferable, an oxime compound is still more preferable, and from the viewpoint of compatibility with other components included in the composition, an oxime compound including a fluorine atom is particularly preferable. In addition, as the oxime compound including a fluorine atom, the above-described compound represented by Formula (OX-1) is preferable. Specific examples of the photopolymerization initiator A1 include (C-13) and (C-14) shown in the specific examples of the oxime compound.

In the photopolymerization initiator A2, the light absorption coefficient at a wavelength of 365 nm in methanol is 1.0×10² mL/g·cm or less, preferably 10 to 1.0×10² mL/g·cm, and more preferably 20 to 1.0×10² mL/g·cm. In addition, the difference between the light absorption coefficient of the photopolymerization initiator A1 at a wavelength of 365 nm in methanol and the light absorption coefficient of the photopolymerization initiator A2 at a wavelength of 365 nm in methanol is preferably 1.0×10³ mL/g·cm or more, more preferably 5.0×10³ to 3.0×10⁴ mL/g·cm, and still more preferably 1.0×10⁴ to 2.0×10⁴ mL/g·cm. In addition, in the photopolymerization initiator A2, the light absorption coefficient at a wavelength of 254 nm in methanol is 1.0×10³ mL/g·cm or more, preferably 1.0×10³ to 1.0×10⁶ mL/g·cm, and more preferably 5.0×10³ to 1.0×10⁵ mL/g·cm.

As the photopolymerization initiator A2, a hydroxyalkylphenone compound, a phenylglyoxylate compound, an aminoalkylphenone compound, or an acylphosphine compound is preferable, a hydroxyalkylphenone compound or a phenylglyoxylate compound is more preferable, and a hydroxyalkylphenone compound is still more preferable. In particular, in a case where a compound including an ethylenically unsaturated group and an alkyleneoxy group is used as a polymerizable monomer, it is assumed that the polymerizable monomer and the photopolymerization initiator A2 are close to each other such that a radical can be generated in the vicinity of the polymerizable monomer to allow the polymerizable monomer to react more effectively, therefore easily forming a pattern having more excellent adhesiveness and solvent resistance. In addition, as the hydroxyalkylphenone compound, the above-described compound represented by Formula (A2-1) is preferable. Specific examples of the photopolymerization initiator A2 include 1-hydroxy-cyclohexyl-phenyl-ketone (as a commercially available product, for example, IRGACURE-184 manufactured by BASF), and 1-[4-(2-hydroxyethoxy)-phenyl]-2-hydroxy-2-methyl-1-propan-1-one (as a commercially available product, for example, IRGACURE-2959 manufactured by BASF).

From the reason that an absorption coefficient of light having a wavelength of more than 350 nm and 380 nm or less and an absorption coefficient of light having a wavelength of 254 nm or more and 350 nm or less can be increased, as a combination of the photopolymerization initiator A1 and the photopolymerization initiator A2, a combination in which the photopolymerization initiator A1 is an oxime compound and the photopolymerization initiator A2 is a hydroxyalkylphenone compound is preferable, a combination in which the photopolymerization initiator A1 is an oxime compound including a fluorine atom and the photopolymerization initiator A2 is the compound represented by Formula (A2-1) is more preferable, and a combination in which the photopolymerization initiator A1 is the compound represented by Formula (OX-1) and the photopolymerization initiator A2 is the compound represented by Formula (A2-1) is still more preferable.

The content of the photopolymerization initiator A1 in the total solid content of the photosensitive coloring composition according to the embodiment of the present invention is preferably 1.0% to 20.0% by mass. From the viewpoint of adhesiveness of the cured film (pattern) after development to a support, the lower limit of the content of the photopolymerization initiator A1 is preferably 2.0% by mass or more, more preferably 3.0% by mass or more, and still more preferably 4.0% by mass or more. From the viewpoint of miniaturization of the pattern after development, the upper limit of the content of the photopolymerization initiator A1 is preferably 15.0% by mass or less, more preferably 12.5% by mass or less, and still more preferably 10.0% by mass or less.

The content of the photopolymerization initiator A2 in the total solid content of the photosensitive coloring composition according to the embodiment of the present invention is preferably 0.5% to 15.0% by mass. From the viewpoint of solvent resistance of the obtained cured film, the lower limit of the content of the photopolymerization initiator A2 is preferably 1.0% by mass or more, more preferably 1.5% by mass or more, and still more preferably 2.0% by mass or more. From the viewpoint of miniaturization of the pattern after development, the upper limit of the content of the photopolymerization initiator A2 is preferably 12.5% by mass or less, more preferably 10.0% by mass or less, and still more preferably 7.5% by mass or less.

It is preferable that the photosensitive coloring composition according to the embodiment of the present invention contains 50 to 200 parts by mass of the photopolymerization initiator A2 with respect to 100 parts by mass of the photopolymerization initiator A1. From the viewpoint of miniaturization of the pattern after development, the upper limit is preferably 175 parts by mass or less and more preferably 150 parts by mass or less. In addition, from the viewpoint of solvent resistance of the obtained cured film, the lower limit is preferably 60 parts by mass or more and still more preferably 70 parts by mass or more.

It is preferable that the total content of the photopolymerization initiator A1 and the photopolymerization initiator A2 in the total solid content of the photosensitive coloring composition according to the embodiment of the present invention is 5% to 15% by mass. From the viewpoint of temporal stability of the composition, the lower limit is preferably 6% by mass or more, more preferably 7% by mass or more, and still more preferably 8% by mass or more. From the viewpoint of miniaturization of the pattern after development, the upper limit is preferably 14.5% by mass or less, more preferably 14.0% by mass or less, and still more preferably 13.0% by mass or less.

The photosensitive coloring composition according to the embodiment of the present invention may contain a photopolymerization initiator (hereinafter, also referred to as other photopolymerization initiators) other than the photopolymerization initiator A1 and the photopolymerization initiator A2 as a photopolymerization initiator, but it is preferable that the photosensitive coloring composition according to the embodiment of the present invention does not substantially contain other photopolymerization initiators. The case where the photosensitive coloring composition according to the embodiment of the present invention does not substantially contain other photopolymerization initiators means that the content of other photopolymerization initiators is preferably 1 part by mass or less, more preferably 0.5 parts by mass or less, still more preferably 0.1 parts by mass or less, and even more preferably 0 parts by mass with respect to 100 parts by mass of the total amount of the photopolymerization initiator A1 and the photopolymerization initiator A2.

<<Polymerizable Monomer>>

The photosensitive coloring composition according to the embodiment of the present invention contains a polymerizable monomer. Examples of the polymerizable monomer include a compound having an ethylenically unsaturated group. Examples of the ethylenically unsaturated group include a vinyl group, a (meth)allyl group, and a (meth)acryloyl group. The polymerizable monomer is preferably a compound (radical polymerizable monomer) which can be polymerized by radicals. In the present specification, a polymerizable compound is a compound different from a coloring material having a polymerizable group. The polymerizable compound is preferably a compound having no coloring agent structure.

The molecular weight of the polymerizable monomer is preferably 100 to 2,000. The upper limit is preferably 1500 or less and more preferably 1,000 or less. The lower limit is more preferably 150 or more and still more preferably 250 or more.

From the viewpoint of temporal stability of the composition, an ethylenically unsaturated group value (hereinafter, referred to as a C═C value) of the polymerizable monomer is preferably 2 to 14 mmol/g. The lower limit is preferably 3 mmol/g or more, more preferably 4 mmol/g or more, and still more preferably 5 mmol/g or more. The upper limit is preferably 12 mmol/g or less, more preferably 10 mmol/g or less, and still more preferably 8 mmol/g or less. The C═C value of the polymerizable monomer is obtained by dividing the number of ethylenically unsaturated groups included in one molecule of the polymerizable monomer by the molecular weight of the polymerizable monomer.

From the reason that a pattern having excellent rectangularity and adhesiveness is easily formed, the polymerizable monomer is preferably a compound including three or more ethylenically unsaturated groups, and more preferably a compound including four or more ethylenically unsaturated groups. The upper limit of the ethylenically unsaturated group is preferably 15 or less, more preferably 10 or less, and still more preferably 6 or less. In addition, the polymerizable monomer is preferably a trifunctional or higher (meth)acrylate compound and more preferably a tetrafunctional or higher (meth)acrylate compound.

It is preferable that the polymerizable monomer is a compound including an ethylenically unsaturated group and an alkyleneoxy group. Since such a polymerizable monomer has high flexibility and the ethylenically unsaturated group is easily moved, the polymerizable monomers easily react with each other in a case of exposure and a pattern having excellent adhesiveness to a support or the like can be formed. In addition, in a case where a hydroxyalkylphenone compound is used as the photopolymerization initiator A2, it is assumed that the polymerizable monomer and the photopolymerization initiator A2 are close to each other such that a radical can be generated in the vicinity of the polymerizable monomer to allow the polymerizable monomer to react more effectively, therefore easily forming a pattern having more excellent adhesiveness and solvent resistance.

From the reason that a pattern having excellent adhesiveness is easily formed, the number of alkyleneoxy groups included in one molecule of the polymerizable monomer is preferably 3 or more and more preferably 4 or more. From the viewpoint of temporal stability of the composition, the upper limit is preferably 20 or less.

In addition, from the viewpoint of compatibility with other components included in the composition, a solubility parameter (SP) value of the compound including an ethylenically unsaturated group and an alkyleneoxy group is preferably 9.0 to 11.0. The upper limit is preferably 10.75 or less and more preferably 10.5 or less. The lower limit is preferably 9.25 or more and more preferably 9.5 or more. In the present specification, the SP value is a calculated value based on Fedors method.

Examples of the compound having an ethylenically unsaturated group and an alkyleneoxy group include a compound represented by Formula (M-1).

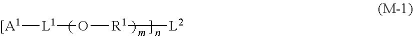

In the formula, A¹ represents an ethylenically unsaturated group, L¹ represents a single bond or a divalent linking group, R¹ represents an alkylene group, m represents an integer of 1 to 30, n represents an integer of 3 or more, and L² represents an n-valent linking group.

Examples of the ethylenically unsaturated group represented by A¹ include a vinyl group, a (meth)allyl group, and a (meth)acryloyl group, and a (meth)acryloyl group is preferable.

Examples of the divalent linking group represented by L¹ include an alkylene group, an arylene group, —O—, —CO—, —COO—, —OCO—, —NH—, and a group formed by a combination of two or more of these groups. The alkylene group preferably has 1 to 30 carbon atoms, more preferably has 1 to 20 carbon atoms, and still more preferably has 1 to 15 carbon atoms. The alkylene group may be any of linear, branched, and cyclic forms. The arylene group preferably has 6 to 30 carbon atoms, more preferably has 6 to 20 carbon atoms, and still more preferably has 6 to 10 carbon atoms.

The alkylene group represented by R¹ preferably has 1 to 10 carbon atoms, more preferably has 1 to 5 carbon atoms, still more preferably has 1 to 3 carbon atoms, particularly preferably has 2 or 3 carbon atoms, and most preferably 2 carbon atoms. The alkylene group represented by R¹ is preferably linear or branched, and more preferably linear. Specific examples of the alkylene group represented by R¹ include an ethylene group and a linear or branched propylene group, and an ethylene group is preferable.

m represents an integer of 1 to 30, and is preferably an integer of 1 to 20, more preferably an integer of 1 to 10, and still more preferably an integer of 1 to 5.

n represents an integer of 3 or more, and is preferably an integer of 4 or more. The upper limit of n is preferably an integer of 15 or less, more preferably an integer of 10 or less, and still more preferably an integer of 6 or less.

Examples of the n-valent linking group represented by L² include an aliphatic hydrocarbon group, an aromatic hydrocarbon group, a heterocyclic group, a group consisting of a combination thereof, and a group of a combination of at least one selected from an aliphatic hydrocarbon group, an aromatic hydrocarbon group, and a heterocyclic group, and at least one selected from —O—, —CO—, —COO—, —OCO—, and —NH—. The aliphatic hydrocarbon group preferably has 1 to 30 carbon atoms, more preferably has 1 to 20 carbon atoms, and still more preferably has 1 to 15 carbon atoms. The aliphatic hydrocarbon group may be any of linear, branched, and cyclic forms, and is preferably linear or branched. The aromatic hydrocarbon group preferably has 6 to 30 carbon atoms, more preferably has 6 to 20 carbon atoms, and still more preferably has 6 to 10 carbon atoms. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be monocyclic or a fused ring. The n-valent linking group represented by L² is also preferably a group derived from a polyfunctional alcohol.

As the compound having an ethylenically unsaturated group and an alkyleneoxy group, a compound represented by Formula (M-2) is more preferable.

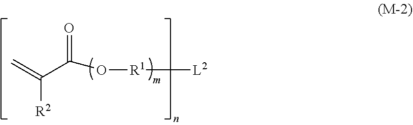

In the formula, R² represents a hydrogen atom or a methyl group, R¹ represents an alkylene group, m represents an integer of 1 to 30, n represents an integer of 3 or more, and L² represents an n-valent linking group. R¹, L², m, and n in Formula (M-2) have the same meaning as R¹, L², m, and n in Formula (M-1), and the preferred ranges are also the same.

Specific examples of the compound having an ethylenically unsaturated group and an alkyleneoxy group include compounds having the following structures. In addition, examples of a commercially available product of the compound having an ethylenically unsaturated group and an alkyleneoxy group include KAYARAD T-1420(T) and RP-1040 (manufactured by Nippon Kayaku Co., Ltd.).

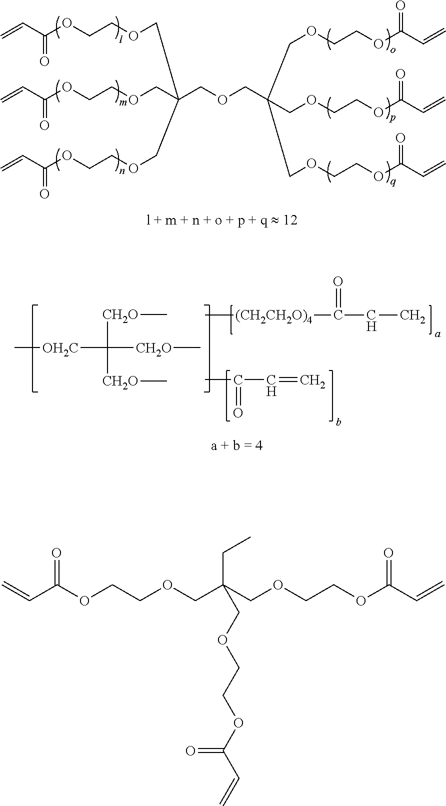

As the polymerizable monomer, a compound such as dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), and a compound having a structure in which the (meth)acryloyl group is bonded through an ethylene glycol and/or a propylene glycol residue (for example, SR454 and SR499 which are commercially available products from Sartomer) can also be used. In addition, as the polymerizable monomer, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

The polymerizable monomer may have an acid group. Examples of the acid group include a carboxyl group, a sulfo group, and a phosphoric acid group, and a carboxyl group is preferable. Examples of a commercially available product of the polymerizable monomer having an acid group include ARONIX M-510, M-520, ARONIX TO-2349 (manufactured by TOAGOSEI CO., LTD).

An acid value of the polymerizable monomer having an acid group is preferably 0.1 to 40 mgKOH/g and more preferably 5 to 30 mgKOH/g. In a case where an acid value of the polymerizable monomer is 0.1 mgKOH/g or more, solubility in a developer is good, and in a case where an acid value of the polymerizable monomer is 40 mgKOH/g or less, it is advantageous in production and handling.

The polymerizable monomer is also preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable monomer, it is also preferable to use compounds described in JP2017-048367A, JP6057891B, and JP6031807B, compounds described in JP2017-194662A, 8UH-1006 and 8UH-1012 (both of which are manufactured by Taisei Fine Chemical Co., Ltd.), Light Acrylate POB-A0 (manufactured by Kyoeisha Chemical Co., Ltd.), and the like.

The content of the polymerizable monomer in the total solid content of the photosensitive coloring composition is 15% by mass or more, and from the viewpoint of rectangularity of the obtained pattern, preferably 17.5% by mass or more and more preferably 19.5% by mass or more. From the reason that the generation of residues after forming a pattern is easily suppressed, the upper limit is preferably 30% by mass or less, more preferably 27.5% by mass or less, and still more preferably 25% by mass or less. The content of the polymerizable monomer in the total solid content of the photosensitive coloring composition is particularly preferably 17.5% to 27.5% by mass.

In addition, it is preferable that the photosensitive coloring composition according to the embodiment of the present invention contains 170 to 345 parts by mass of the polymerizable monomer with respect to 100 parts by mass of the total amount of the photopolymerization initiator A1 and the photopolymerization initiator A2. In a case where the content of the polymerizable monomer is within the above-described range, the effects of the present invention are more remarkably obtained. From the reason that a cured film having excellent rectangularity is easily formed, the lower limit is preferably 200 parts by mass or more and still more preferably 220 parts by mass or more. From the reason that residues after forming a pattern are more easily reduced, the upper limit is preferably 330 parts by mass or less and still more preferably 300 parts by mass or less.

<<Resin>>

The photosensitive coloring composition according to the embodiment of the present invention preferably includes a resin. Examples of the resin include an alkali-soluble resin. The resin is blended in, for example, an application for dispersing particles such as a pigment in a composition or an application as a binder. Mainly, a resin which is used for dispersing particles such as a pigment is also referred to as a dispersant. However, such applications of the resin are only exemplary, and the resin can also be used for other purposes in addition to such applications.

(Alkali-Soluble Resin)

The photosensitive coloring composition according to the embodiment of the present invention preferably includes an alkali-soluble resin. The alkali-soluble resin can be appropriately selected from resins having a group promoting an alkali dissolution. Examples of the group promoting an alkali dissolution (hereinafter, also referred to as an acid group) include a carboxyl group, a phosphoric acid group, a sulfo group, and a phenolic hydroxyl group, and a carboxyl group is preferable. The acid group included in the alkali-soluble resin may be used singly or in combination of two or more kinds thereof.

The weight-average molecular weight (Mw) of the alkali-soluble resin is preferably 5000 to 100,000. In addition, the number-average molecular weight (Mn) of the alkali-soluble resin is preferably 1,000 to 20,000.

An acid value of the alkali-soluble resin is preferably 25 to 200 mgKOH/g. The lower limit is more preferably 30 mgKOH/g or more and still more preferably 40 mgKOH/g or more. The upper limit is more preferably 150 mgKOH/g or less, still more preferably 120 mgKOH/g or less, and particularly preferably 100 mgKOH/g or less.

As the alkali-soluble resin, from the viewpoint of heat resistance, a polyhydroxystyrene-based resin, a polysiloxane-based resin, an acrylic resin, an acrylamide-based resin, or an acrylic/acrylamide copolymer resin is preferable. In addition, from the viewpoint of suppressing developability, an acrylic resin, an acrylamide-based resin, or an acrylic/acrylamide copolymer resin is preferable.

The alkali-soluble resin is preferably a polymer having a carboxyl group in a side chain. Examples thereof include copolymers having a repeating unit derived from a monomer such as a methacrylic acid, an acrylic acid, an itaconic acid, a crotonic acid, a maleic acid, a 2-carboxyethyl(meth)acrylic acid, a vinylbenzoic acid, and a partially esterified maleic acid, alkali-soluble phenol resins such as a novolac type resin, an acidic cellulose derivative having a carboxyl group in a side chain, and a polymer obtained by adding an acid anhydride to a polymer having a hydroxyl group. In particular, a copolymer of a (meth)acrylic acid and another monomer copolymerizable therewith is suitable as the alkali-soluble resin. Examples of another monomer copolymerizable with the (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, glycidyl methacrylate, and tetrahydrofurfuryl methacrylate. Examples of the vinyl compound include styrene, α-methylstyrene, vinyltoluene, acrylonitrile, vinyl acetate, N-vinylpyrrolidone, a polystyrene macromonomer, and a polymethyl methacrylate macromonomer. Such other monomers copolymerizable with (meth)acrylic acids may be used singly or in combination of two or more kinds thereof.

The alkali-soluble resin may have a repeating unit derived from a maleimide compound. Examples of the maleimide compound include N-alkylmaleimide and N-arylmaleimide. Examples of the repeating unit derived from a maleimide compound include a repeating unit represented by Formula (C-mi).

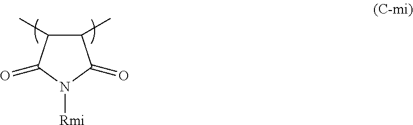

In Formula (C-mi), Rmi represents an alkyl group or an aryl group. The alkyl group preferably has 1 to 20 carbon atoms. The alkyl group may be any of linear, branched, and cyclic forms. The aryl group preferably has 6 to 20 carbon atoms, more preferably has 6 to 15 carbon atoms, and still more preferably has 6 to 10 carbon atoms. Rmi is preferably an aryl group.

As the alkali-soluble resin, a benzyl (meth)acrylate/(meth)acrylic acid copolymer, a benzyl (meth)acrylate/(meth)acrylic acid/2-hydroxyethyl (meth)acrylate copolymer, or a multicomponent copolymer formed of benzyl (meth)acrylate/(meth)acrylic acid/other monomers can be preferably used. In addition, a copolymer obtained by copolymerizing 2-hydroxyethyl (meth)acrylate and other monomers, the 2-hydroxypropyl (meth)acrylate/polystyrene macromonomer/benzyl methacrylate/methacrylic acid copolymer described in JP1995-140654A (JP-H07-140654A), a 2-hydroxy-3-phenoxypropylacrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrylate/methacrylic acid copolymer, and the like can also be preferably used.

As the alkali-soluble resin, an alkali-soluble resin having a polymerizable group can also be used. Examples of the polymerizable group include a (meth)allyl group and a (meth)acryloyl group. As the alkali-soluble resin having a polymerizable group, an alkali-soluble resin having a polymerizable group in a side chain, or the like is useful. Examples of a commercially available product of the alkali-soluble resin having a polymerizable group include Dianal NR Series (manufactured by Mitsubishi Rayon Co., Ltd.), Photomer 6173 (polyurethane acrylate oligomer containing carboxyl group, manufactured by Diamond Shamrock Corp.), Viscoat R-264 and KS Resist 106 (both of which are manufactured by Osaka Organic Chemical Industry Ltd.), Cyclomer P series (for example, ACA230AA) and Placcel CF 200 series (all of which are manufactured by Daicel Corporation), Ebecryl 3800 (manufactured by Daicel UCB Company, Ltd.), Acrycure RD-F8 (manufactured by Nippon Shokubai Co., Ltd.), and DP-1305 (manufactured by Fuji Fine Chemicals).

The alkali-soluble resin is also preferably an alkali-soluble resin including a repeating unit having a hydroxyl group. According to this aspect, affinity with a developer is improved, and a pattern having excellent rectangularity is easily formed. In the alkali-soluble resin including a repeating unit having a hydroxyl group, a hydroxyl group value of the alkali-soluble resin is preferably 30 to 100 mgKOH/g. The lower limit is more preferably 35 mgKOH/g or more and still more preferably 40 mgKOH/g or more. The upper limit is more preferably 80 mgKOH/g or less. In a case where the hydroxyl group value of the alkali-soluble resin is within the above-described range, a pattern having excellent rectangularity is easily formed.

The alkali-soluble resin preferably includes a repeating unit derived from at least one compound selected from a compound represented by Formula (ED1) and a compound represented by Formula (1) of JP2010-168539A (hereinafter, these compounds are also referred to as an “ether dimer”).

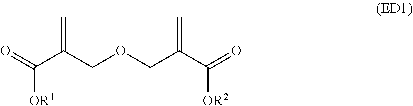

In Formula (ED1), R¹ and R² each independently represent a hydrogen atom or a hydrocarbon group having 1 to 25 carbon atoms, which may have a substituent.

With regard to the ether dimer, reference can be made to paragraph No. 0317 of JP2013-029760A, the contents of which are incorporated herein by reference. The ether dimers may be used singly or in combination of two or more kinds thereof.

Examples of the alkali-soluble resin including a repeating unit derived from the ether dimer include resins having the following structures.

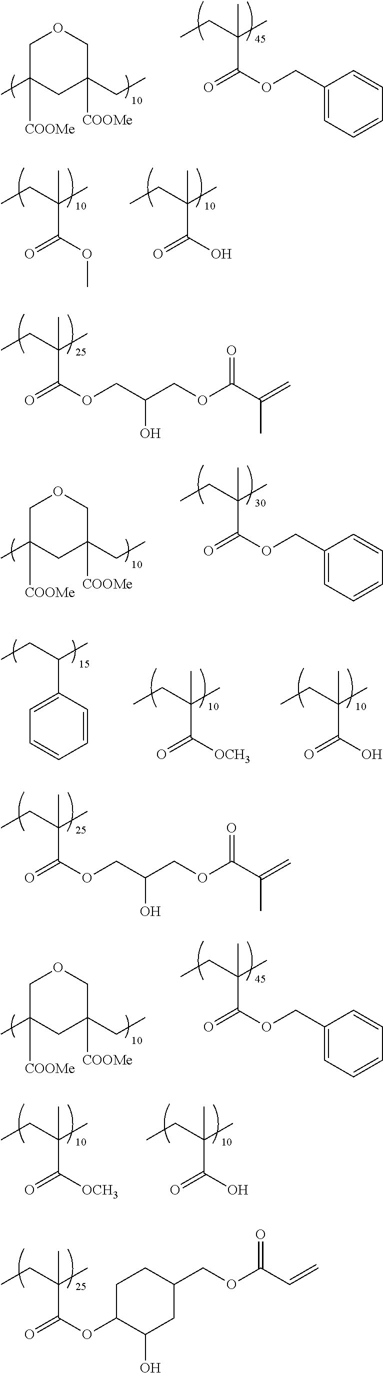

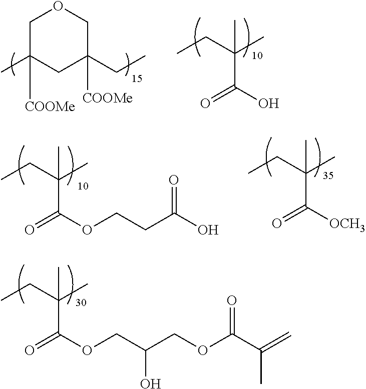

The alkali-soluble resin may include a repeating unit derived from a compound represented by Formula (X).

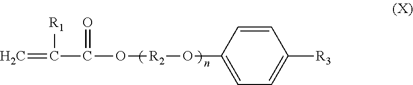

In Formula (X), R¹ represents a hydrogen atom or a methyl group, R² represents an alkylene group having 2 to 10 carbon atoms, and R³ represents a hydrogen atom or an alkyl group having 1 to 20 carbon atoms, which may include a benzene ring. n represents an integer of 1 to 15.

With regard to the alkali-soluble resin, reference can be made to the description in paragraph Nos. 0558 to 0571 of JP2012-208494A (paragraph Nos. 0685 to 0700 of the corresponding US2012/0235099A), the contents of which are incorporated herein by reference. In addition, a copolymer (B) described in paragraph Nos. 0029 to 0063 and alkali-soluble resins used in Examples of JP2012-032767A, binder resins described in paragraph Nos. 0088 to 0098 and binder resins used in Examples of JP2012-208474A, binder resins described in paragraph Nos. 0022 to 0032 and binder resins used in Examples of JP2012-137531A, binder resins described in paragraph Nos. 0132 to 0143 and binder resins used in Examples of JP2013-024934A, binder resins used in paragraph Nos. 0092 to 0098 and Examples of JP2011-242752A, and binder resins described in paragraph Nos. 0030 to 0072 of JP2012-032770A can also be used. The contents of the publications are incorporated herein by reference.

(Dispersant)

The photosensitive coloring composition according to the embodiment of the present invention can contain a resin as a dispersant. Examples of the dispersant include an acidic dispersant (acidic resin) and a basic dispersant (basic resin).

Here, the acidic dispersant (acidic resin) represents a resin in which the amount of the acid group is larger than the amount of the basic group. The acidic dispersant (acidic resin) is preferably a resin in which the amount of the acid group occupies 70% by mole or more in a case where the total amount of the acid group and the basic group is 100% by mole, and more preferably a resin consisting substantially of only an acid group. The acid group contained in the acidic dispersant (acidic resin) is preferably a carboxyl group. An acid value of the acidic dispersant (acidic resin) is preferably 10 to 105 mgKOH/g.

In addition, the basic dispersant (basic resin) represents a resin in which the amount of the basic group is larger than the amount of the acid group. The basic dispersant (basic resin) is preferably a resin in which the amount of the basic group is more than 50% by mole in a case where the total amount of the acid group and the basic group is 100% by mole. The basic group included in the basic dispersant is preferably an amino group.

Examples of the dispersant include polymer dispersants [for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate], polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant adsorbs on a surface of a pigment and acts to prevent reaggregation. Therefore, examples of a preferred structure of the polymer dispersant include a terminal-modified polymer, a graft polymer, and a block polymer, each of which has an anchor site for adsorbing on the pigment surface. In addition, dispersants described in paragraph Nos. 0028 to 0124 of JP2011-070156A or dispersants described in JP2007-277514A are preferably used. The contents of the publications are incorporated herein by reference.

In the present invention, as the resin as a dispersant, an alkali-soluble resin can also be used. In the present invention, as the resin as a dispersant, a graft copolymer can also be used. With regard to details of the graft copolymer, reference can be made to the description in paragraph Nos. 0131 to 0160 of JP2012-137564A, the contents of which are incorporated herein by reference. In addition, in the present invention, as the resin as a dispersant, a resin including a nitrogen atom in a main chain can also be used. The resin including a nitrogen atom in the main chain (hereinafter, also referred to as an oligoimine-based resin) preferably includes at least one repeating unit having a nitrogen atom, selected from a poly(lower alkyleneimine)-based repeating unit, a polyallylamine-based repeating unit, a polydiallylamine-based repeating unit, a metaxylene diamine-epichlorohydrin polycondensate-based repeating unit, and a polyvinylamine-based repeating unit. With regard to the oligoimine-based resin, reference can be made to the description in paragraph Nos. 0102 to 0174 of JP2012-255128A, the contents of which are incorporated herein by reference.

A commercially available product can also be used as the dispersant. For example, a product described in paragraph No. 0129 of JP2012-137564A can also be used as the dispersant. Examples of the commercially available product include DISPERBYK series (for example, DISPERBYK-161 and the like) manufactured by BYK Chemie. The resin described as the dispersant can be used for an application other than the dispersant. For example, the resin can also be used as a binder.

(Other Resins)

The photosensitive coloring composition according to the embodiment of the present invention can contain a resin (also referred to as other resins) other than the above-described dispersant or the alkali-soluble resin as the resin. Examples of the other resins include a (meth)acrylic resin, a (meth)acrylamide resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, and a siloxane resin. Among these resins, one kind may be used alone, or a mixture of two or more kinds may be used as the other resins. In addition, as the resin, resins described in JP2017-167513A can also be used, the contents of which are incorporated herein by reference.

In the photosensitive coloring composition according to the embodiment of the present invention, the content of the resin is preferably 50 to 170 parts by mass with respect to 100 parts by mass of the polymerizable monomer. In a case where the content of the resin is within the above-described range, the effects of the present invention are more remarkably obtained. From the reason that a cured film having excellent adhesiveness is easily formed, the upper limit of the content of the resin is preferably 160 parts by mass or less and more preferably 150 parts by mass or less. From the reason that residues after forming a pattern are more easily reduced, the lower limit of the content of the resin is preferably 60 parts by mass or more and more preferably 75 parts by mass or more. From the reason that residues after forming a pattern can be further reduced and a cured film having excellent adhesiveness is easily formed, the content of the alkali-soluble resin as the resin included in the photosensitive coloring composition according to the embodiment of the present invention is preferably 20% to 100% by mass, more preferably 30% to 100% by mass, still more preferably 40% to 100% by mass, and particularly preferably 50% to 100% by mass.

In addition, in the photosensitive coloring composition according to the embodiment of the present invention, the content of the alkali-soluble resin is preferably 50 to 170 parts by mass with respect to 100 parts by mass of the polymerizable monomer. In a case where the content of the alkali-soluble resin is within the above-described range, the effects of the present invention are more remarkably obtained. The upper limit of the content of the alkali-soluble resin is preferably 160 parts by mass or less and more preferably 150 parts by mass or less. The lower limit of the content of the alkali-soluble resin is preferably 60 parts by mass or more and more preferably 75 parts by mass or more.

In a case where the photosensitive coloring composition according to the embodiment of the present invention contains the resin as a dispersant, the content of the dispersant is preferably 1 to 200 parts by mass with respect to 100 parts by mass of the pigment. The lower limit is preferably 5 parts by mass or more and more preferably 10 parts by mass or more. The upper limit is preferably 150 parts by mass or less and more preferably 100 parts by mass or less.

<<Pigment Derivative>>

The photosensitive coloring composition according to the embodiment of the present invention can contain a pigment derivative. Examples of the pigment derivative include a compound having a structure in which a part of a chromophore is substituted with an acid group, a basic group, or a phthalimidemethyl group. Examples of the chromophore constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton. Among these, a quinoline-based skeleton, a benzimidazolone-based skeleton, a diketopyrrolopyrrole-based skeleton, an azo-based skeleton, a quinophthalone-based skeleton, an isoindoline-based skeleton, or a phthalocyanine-based skeleton is preferable, and an azo-based skeleton or a benzimidazolone-based skeleton is more preferable. As the acid group included in the pigment derivative, a sulfo group or a carboxyl group is preferable and a sulfo group is more preferable. As the basic group included in the pigment derivative, an amino group is preferable and a tertiary amino group is more preferable. With regard to specific examples of the pigment derivative, reference can be made to the description in paragraph Nos. 0162 to 0183 of JP2011-252065A, the contents of which are incorporated herein by reference.

The content of the pigment derivative is preferably 1 to 30 parts by mass and still more preferably 3 to 20 parts by mass with respect to 100 parts by mass of the pigment. The pigment derivative may be used singly or in combination of two or more kinds thereof

<<Compound Having Epoxy Group>>

The photosensitive coloring composition according to the embodiment of the present invention preferably further contains a compound having an epoxy group. According to this aspect, mechanical strength or the like of the obtained cured film can be improved. As the compound having an epoxy group, a compound having two or more epoxy groups in one molecule is preferable. It is preferable to have 2 to 100 epoxy groups in one molecule. The upper limit is, for example, 10 or less or 5 or less.

The epoxy equivalent (=the molecular weight of the compound having an epoxy group/the number of epoxy groups) of the compound having an epoxy group is preferably 500 g/eq or less, more preferably 100 to 400 g/eq, and still more preferably 100 to 300 g/eq.

The compound having an epoxy group may be either a low-molecular-weight compound (for example, a molecular weight of less than 1,000) or a high-molecular-weight compound (macromolecule) (for example, a molecular weight of 1,000 or more, and in a case of a polymer, a weight-average molecular weight of 1,000 or more). The molecular weight (in a case of the polymer, the weight-average molecular weight) of the compound having an epoxy group is preferably 200 to 100,000 and more preferably 500 to 50,000. The upper limit of the molecular weight (in a case of the polymer, the weight-average molecular weight) is preferably 3,000 or less, more preferably 2,000 or less, and still more preferably 1,500 or less.

As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

In a case where the photosensitive coloring composition according to the embodiment of the present invention contains the compound having an epoxy group, the content of the compound having an epoxy group in the total solid content of the photosensitive coloring composition is preferably 0.1% to 40% by mass. The lower limit is, for example, more preferably 0.5% by mass or more, and still more preferably 1% by mass or more. The upper limit is, for example, more preferably 30% by mass or less, and still more preferably 20% by mass or less. These compounds having an epoxy group may be used singly or in combination of two or more kinds thereof. In a case where the compound having an epoxy group is used in combination of two or more kinds thereof, the total amount thereof is preferably within the above-described range. In addition, the content of the compound having an epoxy group is preferably 1 to 400 parts by mass, more preferably 1 to 100 parts by mass, and still more preferably 1 to 50 parts by mass with respect to 100 parts by mass of the polymerizable monomer.

<<Solvent>>

The photosensitive coloring composition according to the embodiment of the present invention preferably contains a solvent. The solvent is preferably an organic solvent. The solvent is not particularly limited as long as it satisfies solubility of the respective components or coatability of the photosensitive coloring composition.

Examples of the organic solvent include the following organic solvents. Examples of esters include ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl alkyloxyacetate esters (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), alkyl 3-alkyloxypropionate esters (for example, methyl 3-alkyloxypropionate and ethyl 3-alkyloxypropionate (for example, methyl 3-methoxypropionate, ethyl 3-methoxypropionate, methyl 3-ethoxypropionate, and ethyl 3-ethoxypropionate)), alkyl 2-alkyloxypropionate esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methyl propionate and ethyl 2-alkyloxy-2-methyl propionate (for example, methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate. Examples of ethers include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate. Examples of ketones include methyl ethyl ketone, cyclohexanone, cyclopentanone, 2-heptanone, and 3-heptanone. Suitable examples of aromatic hydrocarbons include toluene and xylene. However, it is preferable in some cases to reduce aromatic hydrocarbons (benzene, toluene, xylene, ethylbenzene, and the like) (for example, the amount can be set to 50 ppm (parts per million) by mass or less, 10 ppm by mass or less, or 1 ppm by mass or less with respect to the total amount of the organic solvent) as a solvent for a reason such as an environmental aspect. In addition, 3-methoxy-N,N-dimethylpropanamide or 3-butoxy-N, N-dimethylpropanamide is also preferable from the viewpoint of improving the solubility. The organic solvents may be used singly or in combination of two or more kinds thereof. In a case where the organic solvent is used in combination of two or more kinds thereof, the solvent is particularly preferably a mixed solution formed of two or more kinds selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol monomethyl ether acetate.

In the present invention, a solvent having a low metal content is preferably used. For example, the metal content in the solvent is preferably 10 ppb (parts per billion) by mass or less. A solvent in which the metal content is at a level of ppt (parts per trillion) by mass may be used as desired, and such a high-purity solvent is provided by, for example, Toyo Kasei Kogyo Co., Ltd. (The Chemical Daily, Nov. 13, 2015).

Examples of a method for removing impurities such as a metal from the solvent include distillation (for example, molecular distillation and thin-film distillation) and filtration using a filter. The filter pore size of a filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers or a plurality of isomers may be included.

In the present invention, the organic solvent preferably has the content of peroxides of 0.8 mmol/L or less, and more preferably, the organic solvent does not substantially include peroxides.

The content of the solvent is preferably an amount such that the concentration of solid contents (total solid content) of the photosensitive coloring composition is 5% to 80% by mass. The lower limit is preferably 10% by mass or more. The upper limit is preferably 60% by mass or less, more preferably 50% by mass or less, and still more preferably 40% by mass or less.

In addition, from the viewpoint of environmental regulation, it is preferable that the photosensitive coloring composition according to the embodiment of the present invention does not substantially contain environmentally regulated substances. In the present invention, the description “does not substantially contain environmentally regulated substances” means that the content of the environmentally regulated substances in the photosensitive coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent at the time of producing respective components used in the photosensitive coloring composition according to the embodiment of the present invention, and may be incorporated into the photosensitive coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or composition produced by mixing these compounds.

<<Curing Accelerator>>

For the purpose of promoting the reaction of polymerizable monomers or lowering a curing temperature, a curing accelerator may be added to the photosensitive coloring composition according to the embodiment of the present invention. Examples of the curing accelerator include a polyfunctional thiol compound having two or more mercapto groups in a molecule. The polyfunctional thiol compound may also be added for the purpose of alleviating problems in stability, odor, resolution, developability, adhesiveness, or the like. The polyfunctional thiol compound is preferably secondary alkanethiols and more preferably a compound represented by Formula (T1).

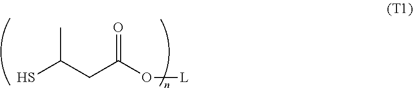

(In Formula (T1), n represents an integer of 2 to 4, and L represents a divalent to tetravalent linking group)

In Formula (T1), the linking group L is preferably an aliphatic group having 2 to 12 carbon atoms, and it is particularly preferable that n is 2 and L is an alkylene group having 2 to 12 carbon atoms.

Moreover, as the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used.

In a case where the photosensitive coloring composition according to the embodiment of the present invention contains a curing accelerator, the content of the curing accelerator in the total solid content of the photosensitive coloring composition is preferably 0.3% to 8.9% by mass and more preferably 0.8% to 6.4% by mass.

<<Surfactant>>

The photosensitive coloring composition according to the embodiment of the present invention can contain a surfactant. As the surfactant, various surfactants such as a fluorine-based surfactant, a nonionic surfactant, a cationic surfactant, an anionic surfactant, and a silicon-based surfactant can be used. With regard to the surfactant, reference can be made to the description in paragraph Nos. 0238 to 0245 of WO2015/166779A, the contents of which are incorporated herein by reference.

In the present invention, it is preferable that the surfactant is a fluorine-based surfactant. By the photosensitive coloring composition containing a fluorine-based surfactant, liquid characteristics (in particular, fluidity) are further improved, and liquid saving properties can be further improved. In addition, a film with small thickness unevenness can be formed.

The fluorine content in the fluorine-based surfactant is preferably 3% to 40% by mass, more preferably 5% to 30% by mass, and still more preferably 7% to 25% by mass. The fluorine-based surfactant in which the fluorine content is within the above-described range is effective in terms of the evenness of the thickness of the coating film or liquid saving properties and the solubility of the surfactant in the photosensitive coloring composition is also good.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include MEGAFACE F171, F172, F173, F176, F177, F141, F142, F143, F144, R30, F437, F475, F479, F482, F554, F780, EXP, and MFS-330 (all of which are manufactured by DIC Corporation), FLUORAD FC430, FC431, and FC171 (all of which are manufactured by Sumitomo 3M), SURFLON S-382, SC-101, SC-103, SC-104, SC-105, SC-1068, SC-381, SC-383, and S-393, and KH-40 (all of which are manufactured by Asahi Glass Co., Ltd.), and PolyFox PF636, PF656, PF6320, PF6520, and PF7002 (all of which are manufactured by OMNOVA).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of the fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

As the fluorine-based surfactant, it is also preferable to use a polymer of a fluorine atom-containing vinyl ether compound having a fluorinated alkyl group or a fluorinated alkylene ether group and a hydrophilic vinyl ether compound. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as a fluorine-based surfactant for use in the present invention. In the following formula, % representing the proportion of the repeating unit is % by mole.

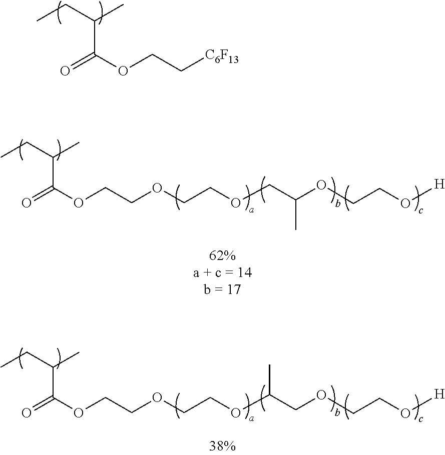

The weight-average molecular weight of the compounds is preferably 3,000 to 50,000, and is, for example, 14,000.

A fluorine-containing polymer having an ethylenically unsaturated group in the side chain can also be used as the fluorine-based surfactant. Specific examples thereof include the compounds described in paragraph Nos. 0050 to 0090 and paragraph Nos. 0289 to 0295 of JP2010-164965A. Examples of a commercially available product thereof include MEGAFACE RS-101, RS-102, RS-718-K, and RS-72-K, all manufactured by DIC Corporation.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Japan Ltd.), NCW-101, NCW-1001, and NCW-1002 (manufactured by Wako Pure Chemical Industries, Ltd.), PIONIN D-6112, D-6112-W, and D-6315 (manufactured by Takemoto Oil & Fat Co., Ltd.), and OLFINE E1010, and SURFYNOL 104, 400, and 440 (manufactured by Nissin Chemical Industry Co., Ltd.).

Examples of the cationic surfactant include an organosiloxane polymer KP341 (manufactured by Shin-Etsu Chemical Co., Ltd.), (meth)acrylic acid-based (co)polymers POLYFLOW No. 75, No. 90, and No. 95 (manufactured by KYOEISHA CHEMICAL CO., LTD.), and W001 (manufactured by Yusho Co., Ltd.).

Examples of the anionic surfactant include W004, W005, and WO17 (manufactured by Yusho Co., Ltd.), and SANDET BL (manufactured by Sanyo Chemical Industries, Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP341, KF6001, and KF6002 (all of which are manufactured by Shin-Etsu Chemical Co., Ltd.), and BYK307, BYK323, and BYK330 (all of which are manufactured by BYK Chemie).

The content of the surfactant in the total solid content of the photosensitive coloring composition is preferably 0.001% to 2.0% by mass and more preferably 0.005% to 1.0% by mass. The surfactant may be used singly or in combination of two or more kinds thereof. In a case where two or more kinds thereof are included, the total amount thereof is preferably within the above-described range.

<<Silane Coupling Agent>>

The photosensitive coloring composition according to the embodiment of the present invention can contain a silane coupling agent. As the silane coupling agent, a silane compound having at least two kinds of functional groups having different reactivity in one molecule is preferable. The silane coupling agent is preferably a silane compound having at least one selected from a vinyl group, an epoxy group, a styrene group, a methacryl group, an amino group, an isocyanurate group, a ureido group, a mercapto group, a sulfide group, or an isocyanate group, and an alkoxy group. Specific examples of the silane coupling agent include N-β-aminoethyl-γ-aminopropyl methyldimethoxysilane (KBM-602, manufactured by Shin-Etsu Chemical Co., Ltd.), N-β-aminoethyl-γ-aminopropyl trimethoxysilane (KBM-603, manufactured by Shin-Etsu Chemical Co., Ltd.), N-β-aminoethyl-γ-aminopropyl triethoxysilane (KBE-602, manufactured by Shin-Etsu Chemical Co., Ltd.), γ-aminopropyl trimethoxysilane (KBM-903, manufactured by Shin-Etsu Chemical Co., Ltd.), γ-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the description in paragraph Nos. 0155 to 0158 of JP2013-254047A, the contents of which are incorporated herein by reference. In a case where the photosensitive coloring composition according to the embodiment of the present invention contains a silane coupling agent, the content of the silane coupling agent in the total solid content of the photosensitive coloring composition is preferably 0.001% to 20% by mass, more preferably 0.01% to 10% by mass, and particularly preferably 0.1% by mass to 5% by mass. The photosensitive coloring composition according to the embodiment of the present invention may include one kind or two or more kinds of the silane coupling agents. In a case where two or more kinds thereof are included, the total amount thereof is preferably within the above-described range.

<<Polymerization Inhibitor>>

The photosensitive coloring composition according to the embodiment of the present invention can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxylamine salt (an ammonium salt, a cerous salt, or the like). In a case where the photosensitive coloring composition according to the embodiment of the present invention contains a polymerization inhibitor, the content of the polymerization inhibitor in the total solid content of the photosensitive coloring composition is preferably 0.001% to 5% by mass. The photosensitive coloring composition according to the embodiment of the present invention may include one kind or two or more kinds of the polymerization inhibitors. In a case where two or more kinds thereof are included, the total amount thereof is preferably within the above-described range.

<<Ultraviolet Absorber>>

The photosensitive coloring composition according to the embodiment of the present invention can contain an ultraviolet absorber. As the ultraviolet absorber, a conjugated diene compound, an aminobutadiene compound, a methyldibenzoyl compound, a coumarin compound, a salicylate compound, a benzophenone compound, a benzotriazole compound, an acrylonitrile compound, a hydroxyphenyltriazine compound, or the like can be used. With regard to details thereof, reference can be made to the description in paragraph Nos. 0052 to 0072 of JP2012-208374A and paragraph Nos. 0317 to 0334 of JP2013-068814A, the contents of which are incorporated herein by reference. Examples of a commercially available product of the ultraviolet absorber include UV-503 (manufactured by Daito Chemical Co., Ltd.). In addition, as the benzotriazole compound, MYUA series manufactured by Miyoshi Oil & Fat Co., Ltd. (The Chemical Daily, Feb. 1, 2016) may be used. In a case where the photosensitive coloring composition according to the embodiment of the present invention contains an ultraviolet absorber, the content of the ultraviolet absorber in the total solid content of the photosensitive coloring composition is preferably 0.1% to 10% by mass, more preferably 0.1% to 5% by mass, and particularly preferably 0.1% to 3% by mass. In addition, the ultraviolet absorber may be used singly or in combination of two or more kinds thereof. In a case where two or more kinds thereof are used, it is preferable that the total amount thereof is within the above-described range.

<<Other Additives>>

Various additives such as a filler, an adhesion promoter, an antioxidant, and an aggregation inhibitor can be blended into the photosensitive coloring composition according to the embodiment of the present invention, as desired. Examples of these additives include the additives described in paragraph Nos. 0155 and 0156 of JP2004-295116A, the contents of which are incorporated herein by reference. In addition, as the antioxidant, for example, a phenol compound, a phosphorus-based compound (for example, the compounds described in paragraph No. 0042 of JP2011-090147A), a thioether compound, or the like can be used. Examples of a commercially available product thereof include ADEKA STAB series (AO-20, AO-30, AO-40, AO-50, AO-50F, AO-60, AO-60G, AO-80, AO-330, and the like) manufactured by ADEKA Corporation. In addition, as the antioxidant, polyfunctional hindered amine antioxidants described in WO2017/006600A and antioxidants described in WO2017/164024A can also be used. The antioxidant may be used singly or in combination of two or more kinds thereof. In addition, as desired, the photosensitive coloring composition according to the embodiment of the present invention may contain a potential antioxidant. Examples of the potential antioxidant include a compound in which a site functioning as an antioxidant is protected by a protecting group, and the protecting group is eliminated by heating the compound at 100° C. to 250° C. or heating the compound at 80° C. to 200° C. in the presence of an acid or basic catalyst and the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation). In addition, the photosensitive coloring composition according to the embodiment of the present invention can contain the sensitizers or the light stabilizers described in paragraph No. 0078 of JP2004-295116A, or the thermal polymerization inhibitors described in paragraph No. 0081 of the same publication.

There are some cases where metal elements are included in the photosensitive coloring composition according to raw materials and the like to be used, but from the viewpoint of suppression of generation of defects, or the like, the content of Group 2 elements (calcium, magnesium, and the like) in the coloring composition is preferably 50 ppm by mass or less, and more preferably 0.01 to 10 ppm by mass. In addition, the total amount of inorganic metal salts in the photosensitive coloring composition is preferably 100 ppm by mass or less and more preferably 0.5 to 50 ppm by mass.

The moisture content in the photosensitive coloring composition according to the embodiment of the present invention is usually 3% by mass or less, preferably 0.01% to 1.5% by mass, and more preferably in a range of 0.1% to 1.0% by mass. The moisture content can be measured by a Karl Fischer method.

The photosensitive coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa×s to 50 mPa×s, and more preferably 0.5 mPa×s to 20 mPa×s at 25° C. As for a method for measuring the viscosity, the viscosity can be measured, for example, with a temperature being adjusted to 25° C., using a viscometer RE85L (rotor: 1°34′×R24, measurement range of 0.6 to 1,200 mPa×s) manufactured by Toki Sangyo Co., Ltd.

A storage container for the photosensitive coloring composition according to the embodiment of the present invention is not particularly limited, and a known storage container can be used. In addition, as the storage container, it is also preferable to use a multilayer bottle having an inner wall constituted with six layers from six kinds of resins or a bottle having a 7-layer structure from 6 kinds of resins for the purpose of suppressing incorporation of impurities into raw materials or compositions. Examples of such a container include the containers described in JP2015-123351A.

The photosensitive coloring composition according to the embodiment of the present invention can be preferably used as a photosensitive coloring composition for forming a color pixel in a color filter. Examples of the color pixel include a red pixel, a green pixel, a blue pixel, a magenta pixel, a cyan pixel, and a yellow pixel.

In a case where the photosensitive coloring composition according to the embodiment of the present invention is used as a color filter in applications for a liquid crystal display device, the voltage holding ratio of a liquid crystal display element including the color filter is preferably 70% or more and more preferably 90% or more. A known method for obtaining a high voltage holding ratio can be appropriately incorporated, and examples of typical methods include use of high-purity materials (for example, reduction in ionic impurities) and control of the amount of acidic functional groups in a composition. The voltage holding ratio can be measured by, for example, the methods described in paragraph 0243 of JP2011-008004A and paragraphs 0123 to 0129 of JP2012-224847A.

<Method for Preparing Photosensitive Coloring Composition>

The photosensitive coloring composition according to the embodiment of the present invention can be prepared by mixing the above-described components. In the preparation of the photosensitive coloring composition, all the components may be dissolved and/or dispersed at the same time in a solvent to prepare the photosensitive coloring composition, or the respective components may be appropriately left in two or more solutions or dispersion liquids and mixed to prepare the photosensitive coloring composition upon use (during coating), as desired.

In addition, in a case of preparing a photosensitive coloring composition including a pigment, in the preparation of the photosensitive coloring composition, it is also preferable to include a process for dispersing the pigment. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, the equipment, the treatment conditions, and the like used in the salt milling step, reference can be made to, for example, the description in JP2015-194521A and JP2012-046629A.

It is preferable that, in the preparation of the photosensitive coloring composition, the photosensitive coloring composition is filtered through a filter for the purpose of removing foreign matters, reducing defects, or the like. As the filter, any filters that have been used in the related art for filtration use and the like may be used without particular limitation. Examples of the filter include filters formed of materials including, for example, a fluorine resin such as polytetrafluoroethylene (PTFE), a polyamide-based resin such as nylon (for example, nylon-6 and nylon-6,6), and a polyolefin resin (including a polyolefin resin having a high-density or an ultrahigh molecular weight) such as polyethylene and polypropylene (PP). Among these materials, polypropylene (including a high-density polypropylene) and nylon are preferable. The pore size of the filter is suitably approximately 0.01 to 7.0 μm, preferably approximately 0.01 to 3.0 μm, and still more preferably approximately 0.05 to 0.5 μm. In a case where the pore size of the filter is within the above-described range, fine foreign matters can be reliably removed. In addition, it is preferable that a fibrous filter material is used. Examples of the fibrous filter material include a polypropylene fiber, a nylon fiber, and a glass fiber. Specific examples thereof include filter cartridges of SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. Here, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Cured Film>

The cured film according to an embodiment of the present invention is a cured film obtained from the above-described photosensitive coloring composition according to the embodiment of the present invention. The cured film according to the embodiment of the present invention can be preferably used as a color pixel of a color filter. Examples of the color pixel include a red pixel, a green pixel, a blue pixel, a magenta pixel, a cyan pixel, and a yellow pixel. The film thickness of the cured film can be appropriately adjusted depending on purposes. For example, the film thickness is preferably 20.0 μm or less, more preferably 10.0 μm or less, still more preferably 5.0 μm or less, even more preferably 4.0 μm or less, and particularly preferably 2.5 μm or less. The lower limit is preferably 0.1 μm or more, more preferably 0.2 μm or more, and still more preferably 0.5 μm or more.

<Method for Forming Pattern>

The method for forming a pattern according to an embodiment of the present invention includes:

a step of forming a photosensitive coloring composition layer on a support using the photosensitive coloring composition according to the embodiment of the present invention;

a step of irradiating the photosensitive coloring composition layer with a light having a wavelength of more than 350 nm and 380 nm or less to patternwise expose the photosensitive coloring composition layer;

a step of developing the photosensitive coloring composition layer after the exposure; and

a step of irradiating the photosensitive coloring composition layer after the development with a light having a wavelength of 254 to 350 nm to expose the photosensitive coloring composition layer after the development.

Furthermore, a step of baking the photosensitive coloring composition layer (pre-baking step) and a step of baking the developed pattern (post-baking step) may be provided after forming the photosensitive coloring composition layer on the support and before exposing the photosensitive coloring composition layer, as desired. Hereinafter, the respective steps will be described.

In the step of forming a photosensitive coloring composition layer, the photosensitive coloring composition layer is formed on a support using the photosensitive coloring composition.

The support is not particularly limited, and can be appropriately selected depending on applications. Examples of the support include a glass substrate, a substrate for a solid-state imaging element, on which a solid-state imaging element (light-receiving element) is provided, and a silicon substrate. In addition, an undercoat layer may be provided on these substrates so as to improve adhesion to an upper layer, prevent the diffusion of substances, or planarize the surface.

As a method for applying the photosensitive coloring composition onto the support, various coating methods such as slit coating, an ink jet method, spin coating, cast coating, roll coating, and a screen printing method can be used.

The photosensitive coloring composition layer formed on the support may be dried (pre-baked). In a case of forming a pattern by a low-temperature process, the pre-baking may not be performed. In a case of performing the pre-baking, the pre-baking temperature is preferably 120° C. or lower, more preferably 110° C. or lower, and still more preferably 105° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the photosensitive coloring composition layer is irradiated with light having a wavelength of more than 350 nm and 380 nm or less to patternwise expose the photosensitive coloring composition layer. For example, the photosensitive coloring composition layer can be subjected to patternwise exposure by performing exposure using an exposure device such as a stepper through a mask having a predetermined mask pattern. Thus, an exposed portion of the photosensitive coloring composition layer can be cured. The radiation (light) which can be used in a case of the exposure is light with a wavelength of more than 350 nm and 380 nm or less, preferably light with a wavelength of 355 to 370 nm, and more preferably i-rays. The irradiation dose (exposure dose) is, for example, preferably 30 to 1500 mJ/cm² and more preferably 50 to 1000 mJ/cm². The oxygen concentration during the exposure can be appropriately selected, and the exposure may also be performed, for example, in a low-oxygen atmosphere having an oxygen concentration of 19% by volume or less (for example, 15% by volume, 5% by volume, or substantially oxygen-free) or in a high-oxygen atmosphere having an oxygen concentration of more than 21% by volume (for example, 22% by volume, 30% by volume, or 50% by volume), in addition to an atmospheric air. Further, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

The reaction rate of the polymerizable monomer in the photosensitive coloring composition layer after exposure is preferably more than 30% and less than 60%. With such a reaction rate, it is possible to bring the polymerizable monomer into a moderately cured state. Here, the reaction rate of the polymerizable monomer refers to a proportion of reacted polymerizable groups in polymerizable groups included in the polymerizable monomers.

Next, the photosensitive coloring composition layer after exposure is developed. That is, a photosensitive coloring composition layer in an unexposed area is removed using a developer to form a pattern. The temperature of the developer is preferably, for example, 20° C. to 30° C. The development time is preferably 20 to 300 seconds.

As the developer, an aqueous alkaline solution (alkaline developer) obtained by diluting an alkali agent with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001% to 10% by mass and more preferably 0.01% to 1% by mass. In addition, the developer may further contain a surfactant. Examples of the surfactant include the surfactants described above, and the surfactant is preferably a nonionic surfactant. From the viewpoints of transportation, storage, and the like, the developer may be first produced as a concentrated liquid and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the photosensitive coloring composition layer after development while rotating the support on which the photosensitive coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

Next, the photosensitive coloring composition layer after development is irradiated with light having a wavelength of 254 to 350 nm to expose the photosensitive coloring composition layer after development. Hereinafter, the exposure after development is also referred to as a post-exposure. The radiation (light) which can be used in a case of the post-exposure is preferably ultraviolet rays at a wavelength of 254 to 300 nm and more preferably ultraviolet rays at a wavelength of 254 nm. The post-exposure can be performed using, for example, an ultraviolet photoresist curing device. The light having a wavelength of 254 to 350 nm and other light (for example, i-rays) may irradiate from the ultraviolet photoresist curing device.

The difference between the wavelength of the light used for the exposure before development and the wavelength of the light used for the exposure (post-exposure) after development is preferably 200 nm or less and more preferably 100 to 150 nm. The irradiation dose (exposure dose) is preferably 30 to 4000 mJ/cm² and more preferably 50 to 3500 mJ/cm². The oxygen concentration in a case of the exposure can be appropriately selected. Examples thereof include the conditions described in the exposure step before development.

The reaction rate of the polymerizable monomer in the photosensitive coloring composition layer after the post-exposure is preferably 60% or more. The upper limit may be 100% or less, or 90% or less. With such a reaction rate, it is possible to improve the cured state of the photosensitive coloring composition layer after exposure.

In the present invention, by exposing the photosensitive coloring composition layer in two stages before and after development, the photosensitive coloring composition can be moderately cured in the first exposure (exposure before development) and the entire photosensitive coloring composition can be cured almost completely in the next exposure (exposure after development). As a result, even under low-temperature conditions, it is possible to sufficiently cure the photosensitive coloring composition and form a pattern having excellent solvent resistance, adhesiveness, and rectangularity.

In the pattern formation of the present invention, a post-baking may be further performed after the post-exposure. In a case of performing the post-baking, in a case where an organic electroluminescence element is used as a light-emitting source of an image display device or a case where a photoelectric conversion film of an image sensor is composed of an organic material, it is preferable to perform a heat treatment (post-baking) at 50° C. to 120° C. (more preferably 80° C. to 100° C. and still more preferably 80° C. to 90° C.). The post-baking can be performed continuously or batchwise by using a heating unit such as a hot plate, a convection oven (hot-air circulating dryer), and a high-frequency heater. In addition, in a case of forming a pattern by a low-temperature process, the post-baking may not be performed.

The thickness of the pattern (hereinafter, also referred to as a pixel) after the post-exposure (in a case of performing the post-baking after the post-exposure, after the post-baking) is preferably 0.1 to 5.0 The lower limit is preferably 0.2 μm or more and more preferably 0.5 μm or more. The upper limit is preferably 4.0 μm or less and more preferably 2.5 μm or less.

The width of the pixel is preferably 0.5 to 20.0 The lower limit is preferably 1.0 μm or more and more preferably 2.0 μm or more. The upper limit is preferably 15.0 μm or less and more preferably 10.0 μm or less.

The Young's modulus of the pixel is preferably 0.5 to 20 GPa and more preferably 2.5 to 15 GPa.

It is preferable that the pixel has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness can be measured, for example, using an atomic force microscope (AFM) Dimension 3100 manufactured by Veeco Instruments, Inc.

In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.).

It is desired that the volume resistivity value of the pixel is high. Specifically, the volume resistivity value of the pixel is preferably 10⁹Ω×cm or more and more preferably 10¹¹Ω×cm or more. The upper limit is not specified, but is, for example, preferably 10¹⁴Ω×cm or less. The volume resistivity value of the pixel can be measured, for example, using an ultra-high resistance meter 5410 (manufactured by Advantest Corporation).

<Color Filter>

Next, the color filter according to an embodiment of the present invention will be described. The color filter according to the embodiment of the present invention has the cured film according to the embodiment of the present invention. In the color filter according to the embodiment of the present invention, the film thickness of the cured film can be appropriately adjusted depending on the purpose. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more. The color filter according to the embodiment of the present invention can be used for a solid-state imaging element such as a charge coupled device (CCD) and a complementary metal-oxide semiconductor (CMOS), an image display device, or the like.

<Solid-State Imaging Element>

The solid-state imaging element according to an embodiment of the present invention has the cured film according to the embodiment of the present invention. The configuration of the solid-state imaging element according to the embodiment of the present invention is not particularly limited as long as the solid-state imaging element is configured to include the cured film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. In addition, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which a cured film forming each coloring pixel is embedded in a space partitioned in a lattice form by a partition wall. The partition wall in this case preferably has a low refractive index for each coloring pixel. Examples of an imaging device having such a structure include the devices described in JP2012-227478A and JP2014-179577A. An imaging device including the solid-state imaging element according to the embodiment of the present invention can also be used as a vehicle camera or a monitoring camera, in addition to a digital camera or electronic equipment (mobile phones or the like) having an imaging function.

<Image Display Device>

The cured film according to the embodiment of the present invention can be used for an image display device such as a liquid crystal display device and an organic electroluminescence display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Preparation of Photosensitive Coloring Composition>

### Example 1

The following raw materials were mixed and stirred, and the obtained mixture was filtered through a nylon filter (manufactured by Pall Corporation) having a pore size of 0.45 to prepare a photosensitive coloring composition.

| | | |
|---|---|---|
| Pigment dispersion liquid (G1) | 72.5 | parts by mass |
| Photopolymerization initiator a (initiator 1) | 1.16 | parts by mass |
| Photopolymerization initiator b (initiator 4) | 0.87 | parts by mass |
| 40% by mass of alkali-soluble resin (resin A) in propylene glycol monomethyl ether | 6.31 | parts by mass |
| acetate solution | | |
| Polymerizable monomer (M1) | 4.77 | parts by mass |
| Polymerization inhibitor (p-methoxyphenol) | 0.002 | parts by mass |
| Surfactant (1% by mass of compound having the following structure (Mw = 14,000, numerical | 0.83 | parts by mass |
| values of % indicating the ratio of repeating units is mol %) in propylene glycol monomethyl | | |
| ether acetate solution) | | |

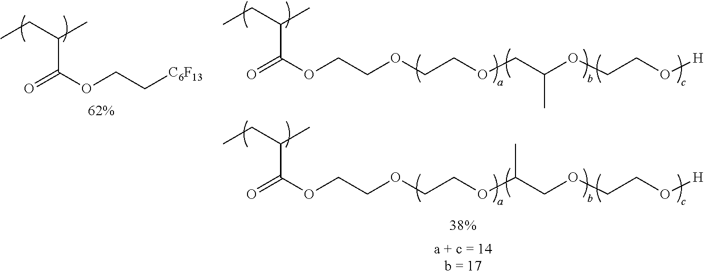

| | | |
|---|---|---|
| Propylene glycol monomethyl ether acetate | 13.48 | parts by mass |

### Examples 2 to 18 and Comparative Examples 1 to 3

By changing each of the type of the pigment dispersion liquid, the type and content of the photopolymerization initiator, and the type and content of the polymerizable monomer as shown in the following table, photosensitive coloring compositions were prepared in the same manner as in Example 1. The numerical value of content shown in the column of the content of the polymerizable monomer in the following table is a content in the total solid content of the photosensitive coloring composition. Regarding Example 10, the blending amount R1 of the pigment dispersion liquid was set to 79.5 parts by mass. In addition, regarding Example 11, the blending amount B1 of the pigment dispersion liquid was set to 68.4 parts by mass.

TABLE 1

| | | Photopolymerization initiator | | | | | |
|---|---|---|---|---|---|---|---|
| | Pigment | | | Photopolymerization | | | Polymerizable |
| | dispersion | Type of | Type of | initiator b/ | Polymerizable | | monomer/ |
| | liquid | photopolymerization | photopolymerization | photopolymerization | monomer | | photopolymerization |
| | Type | initiator a | initiator b | initiator a (mass ratio) | Type | Content | initiator (mass ratio) |
| Example 1 | G1 | Initiator A1-1 | Initiator A2-1 | 75/100 | M1 | 21% by | 235/100 |
| | | | | | | mass | |
| Example 2 | G1 | Initiator A1-1 | Initiator A2-1 | 75/100 | M1 | 15% by | 235/100 |
| | | | | | | mass | |
| Example 3 | G1 | Initiator A1-1 | Initiator A2-1 | 75/100 | M1 | 18% by | 235/100 |
| | | | | | | mass | |
| Example 4 | G1 | Initiator A1-1 | Initiator A2-1 | 75/100 | M1 | 25% by | 235/100 |
| | | | | | | mass | |
| Example 5 | G1 | Initiator A1-1 | Initiator A2-1 | 75/100 | M1 | 30% by | 235/100 |
| | | | | | | mass | |
| Example 6 | G1 | Initiator A1-2 | Initiator A2-1 | 75/100 | M1 | 21% by | 235/100 |
| | | | | | | mass | |
| Example 7 | G1 | Initiator A1-1 | Initiator A2-2 | 75/100 | M1 | 21% by | 235/100 |
| | | | | | | mass | |
| Example 8 | G2 | Initiator A1-1 | Initiator A2-1 | 75/100 | M1 | 21% by | 235/100 |
| | | | | | | mass | |
| Example 9 | G3 | Initiator A1-1 | Initiator A2-1 | 75/100 | M1 | 21% by | 235/100 |
| | | | | | | mass | |
| Example 10 | R1 | Initiator A1-1 | Initiator A2-1 | 75/100 | M1 | 21% by | 235/100 |
| | | | | | | mass | |
| Example 11 | B1 | Initiator A1-1 | Initiator A2-1 | 75/100 | M1 | 21% by | 235/100 |
| | | | | | | mass | |
| Example 12 | G1 | Initiator A1-1 | Initiator A2-1 | 75/100 | M2 | 21% by | 235/100 |
| | | | | | | mass | |
| Example 13 | G1 | Initiator A1-1 | Initiator A2-1 | 75/100 | M3 | 21% by | 235/100 |
| | | | | | | mass | |
| Example 14 | G1 | Initiator A1-1 | Initiator A2-1 | 75/100 | M4 | 21% by | 235/100 |
| | | | | | | mass | |
| Example 15 | G1 | Initiator A1-1 | Initiator A2-1 | 40/100 | M1 | 21% by | 235/100 |
| | | | | | | mass | |
| Example 16 | G1 | Initiator A1-1 | Initiator A2-1 | 240/100 | M1 | 21% by | 235/100 |
| | | | | | | mass | |
| Example 17 | G1 | Initiator A1-1 | Initiator A2-1 | 75/100 | M1 | 21% by | 160/100 |
| | | | | | | mass | |
| Example 18 | G1 | Initiator A1-1 | Initiator A2-1 | 75/100 | M1 | 21% by | 360/100 |
| | | | | | | mass | |
| Comparative | G1 | Initiator A1-1 | — | — | M1 | 21% by | 235/100 |
| Example 1 | | | | | | mass | |
| Comparative | G1 | — | Initiator A2-1 | — | M1 | 21% by | 235/100 |
| Example 2 | | | | | | mass | |
| Comparative | G1 | Initiator R1 | Initiator A2-1 | 75/100 | M1 | 21% by | 235/100 |
| Example 3 | | | | | | mass | |

The raw materials described in the above table are as follows.

(Pigment Dispersion Liquid)

G1: pigment dispersion liquid prepared by the following method

230 parts by mass of zirconia beads having a diameter of 0.3 mm were added to a mixed solution obtained by mixing 7.4 parts by mass of C. I. Pigment Green 36, 5.2 parts by mass of C. I. Pigment Yellow 185, 1.4 parts by mass of a pigment derivative 1, 4.86 parts by mass of a dispersant 1, and 81.14 parts by mass of propylene glycol monomethyl ether acetate (PGMEA), the mixture was subjected to a dispersion treatment for 3 hours using a paint shaker, and the beads were separated by filtration to prepare a pigment dispersion liquid G1. The concentration of solid contents of the pigment dispersion liquid G1 was 18.86% by mass, and the content of the pigment was 14.00% by mass.

Pigment derivative 1: compound having the following structure

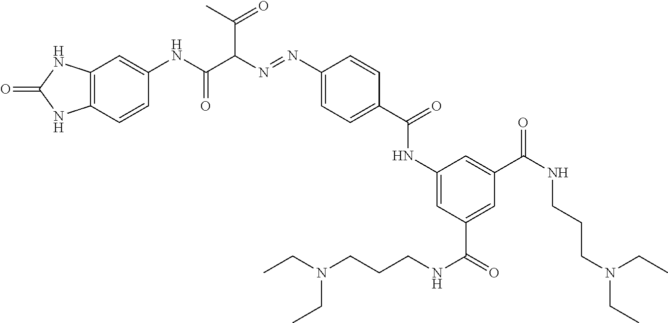 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Dispersant 1: resin having the following structure (Mw=24,000; a numerical value added to the main chain represents a molar ratio, and a numerical value added to the side chain represents the number of repeating units)

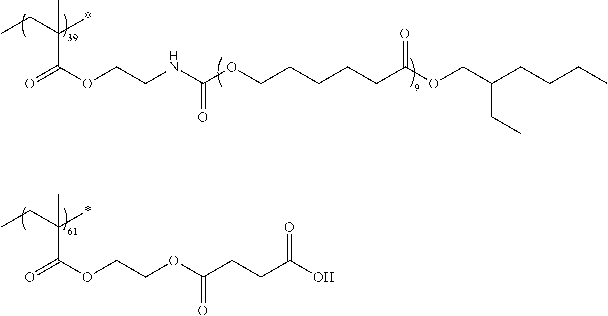

G2: pigment dispersion liquid prepared by the following method

230 parts by mass of zirconia beads having a diameter of 0.3 mm were added to a mixed solution obtained by mixing 8.8 parts by mass of C. I. Pigment Green 58, 3.8 parts by mass of C. I. Pigment Yellow 185, 1.4 parts by mass of the pigment derivative 1, 4.86 parts by mass of the dispersant 1, and 81.14 parts by mass of propylene glycol monomethyl ether acetate (PGMEA), the mixture was subjected to a dispersion treatment for 3 hours using a paint shaker, and the beads were separated by filtration to prepare a pigment dispersion liquid G2. The concentration of solid contents of the pigment dispersion liquid G2 was 18.86% by mass, and the content of the pigment was 14.00% by mass.

G3: pigment dispersion liquid prepared by the following method

230 parts by mass of zirconia beads having a diameter of 0.3 mm were added to a mixed solution obtained by mixing 7.1 parts by mass of C. I. Pigment Green 36, 4.2 parts by mass of C. I. Pigment Yellow 185, 1.3 parts by mass of C. I. Pigment Yellow 139, 1.4 parts by mass of the pigment derivative 1, 4.86 parts by mass of the dispersant 1, and 81.14 parts by mass of propylene glycol monomethyl ether acetate (PGMEA), the mixture was subjected to a dispersion treatment for 3 hours using a paint shaker, and the beads were separated by filtration to prepare a pigment dispersion liquid G3. The concentration of solid contents of the pigment dispersion liquid G3 was 18.86% by mass, and the content of the pigment was 14.00% by mass.

R1: pigment dispersion liquid prepared by the following method

230 parts by mass of zirconia beads having a diameter of 0.3 mm were added to a mixed solution obtained by mixing 8.0 parts by mass of C. I. Pigment Red 254, 3.5 parts by mass of C. I. Pigment Yellow 139, 1.4 parts by mass of the pigment derivative 1, 4.3 parts by mass of the dispersant 1, and 82.8 parts by mass of propylene glycol monomethyl ether acetate (PGMEA), the mixture was subjected to a dispersion treatment for 3 hours using a paint shaker, and the beads were separated by filtration to prepare a pigment dispersion liquid R1. The concentration of solid contents of the pigment dispersion liquid R1 was 17.2% by mass, and the content of the pigment was 12.9% by mass.

B1: pigment dispersion liquid prepared by the following method

230 parts by mass of zirconia beads having a diameter of 0.3 mm were added to a mixed solution obtained by mixing 9.5 parts by mass of C. I. Pigment Blue 15:6, 5.0 parts by mass of C. I. Pigment Violet 23, 5.5 parts by mass of the dispersant 1, and 80.0 parts by mass of propylene glycol monomethyl ether acetate (PGMEA), the mixture was subjected to a dispersion treatment for 3 hours using a paint shaker, and the beads were separated by filtration to prepare a pigment dispersion liquid B1. The concentration of solid contents of the pigment dispersion liquid B1 was 20.0% by mass, and the content of the pigment was 14.5% by mass.

(Photopolymerization Initiator)

Initiator A1-1: compound (A1-1) having the following structure (light absorption coefficient at a wavelength of 365 nm in methanol was 18900 mL/g·cm)

Initiator A1-2: compound (A1-2) having the following structure (light absorption coefficient at a wavelength of 365 nm in methanol was 13200 mL/g·cm)

Initiator A2-1: compound (A2-1) having the following structure (light absorption coefficient at a wavelength of 365 nm in methanol was 48.93 mL/g·cm and light absorption coefficient at a wavelength of 254 nm was 3.0×10⁴ mL/g·cm)

Initiator A2-2: compound (A2-2) having the following structure (light absorption coefficient at a wavelength of 365 nm in methanol was 88.64 mL/g·cm and light absorption coefficient at a wavelength of 254 nm was 3.3×10⁴ mL/g·cm)

Initiator R1: compound (R1) having the following structure (light absorption coefficient at a wavelength of 365 nm in methanol was 6969 mL/g·cm)

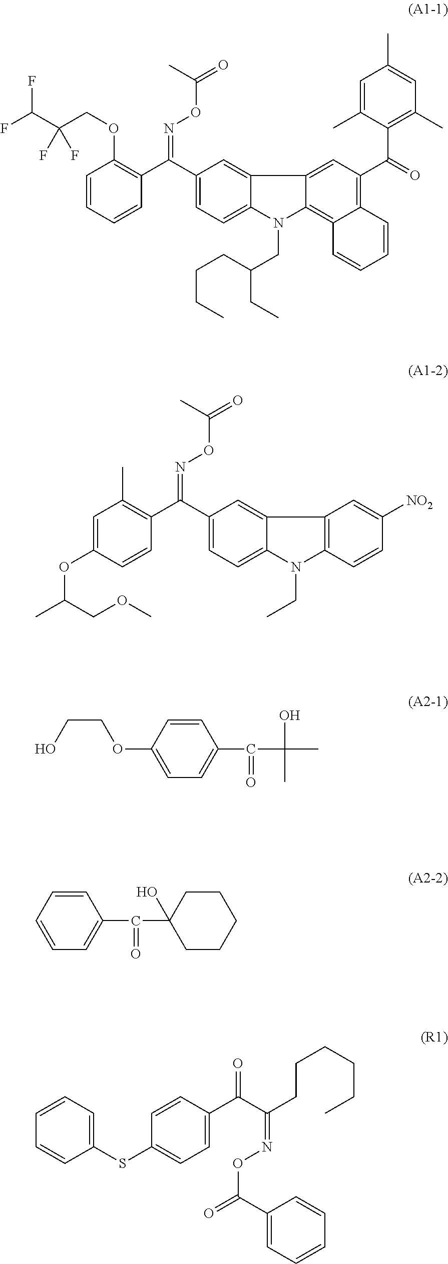

(Polymerizable Monomer)

M1 to M4: compounds having the following structures

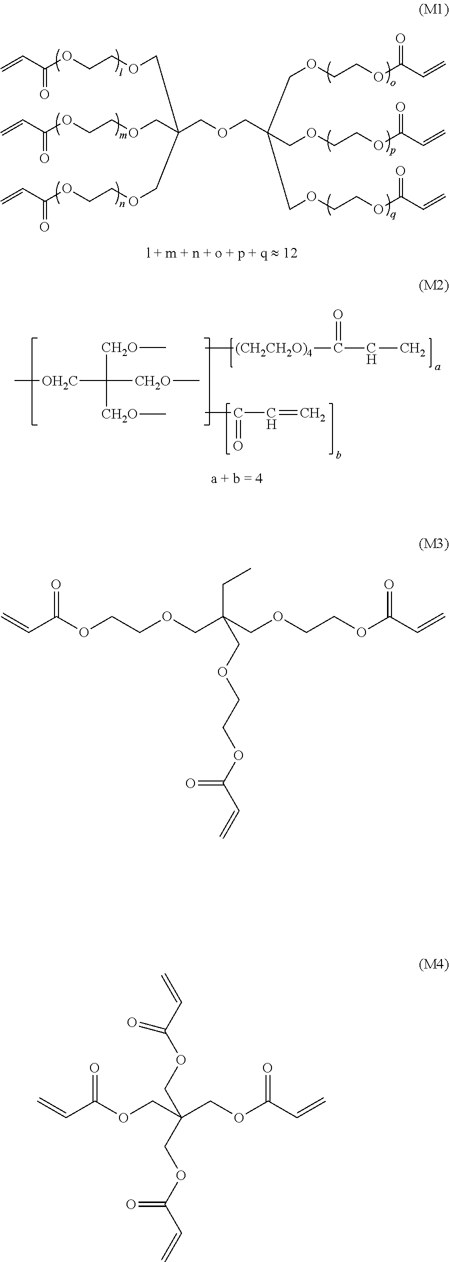

(Alkali-Soluble Resin)

Resin A: resin having the following structure (Mw=11,000, acid value=31.5 mgKOH/g; a numerical value added to the main chain represents a molar ratio)

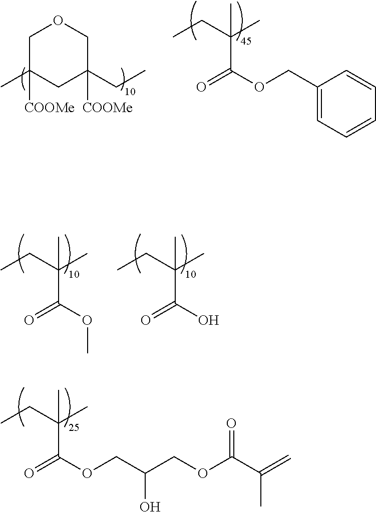

<Evaluation>

(Solvent Resistance) Each photosensitive coloring composition was applied to a glass substrate using a spin coater such that the film thickness after pre-baking was 1.6 and a heat treatment (pre-baking) was performed for 120 seconds using a hot plate at 100° C.

Next, using an ultraviolet photoresist curing device (UMA-802-HC-552, manufactured by USHIO INC.), the film was subjected to an exposure with an exposure dose of 3000 mJ/cm² to produce a cured film.

Using a spectrophotometer (reference: glass substrate) of UV-VIS-NIR Spectrophotometer UV3600 (manufactured by Shimadzu Corporation), the light transmittance of the obtained cured film in a wavelength range of 300 to 800 nm was measured. In addition, using an optical microscope BX60 manufactured by Olympus Corporation, the differential interference image was observed by reflection observation (magnification: 50 times). Next, the cured film was immersed in an alkaline developer (FHD-5, manufactured by FUJIFILM Electronic Materials Co., Ltd.) at 25° C. for 5 minutes, dried, and then subjected to the spectrometry again, and variation in transmittance before and after the immersion in the alkaline developer was obtained to evaluate solvent resistance according to the following standard.

Variation in transmittance=|T0−T1|

T0 is a transmittance of the cured film before the immersion in the alkaline developer and T1 is a transmittance of the cured film after the immersion in the alkaline developer.

AA: variation in transmittance in the entire wavelength range of 300 to 800 nm was less than 2%.

A: variation in transmittance in the entire wavelength range of 300 to 800 nm was less than 5%, and variation in transmittance in a part of the range was 2% or more and less than 5%.

B: variation in transmittance in the entire wavelength range of 300 to 800 nm was less than 10%, and variation in transmittance in a part of the range was 5% or more and less than 10%.

C: variation in transmittance in at least a part of a wavelength range of 300 to 800 nm was 10% or more.

(Evaluation of Adhesiveness, Residue, and Rectangularity)

Each photosensitive coloring composition was applied to an 8-inch (20.32 cm) silicon wafer sprayed with hexamethyldisilazane using a spin coater such that the film thickness after pre-baking was 1.6 μm, and a heat treatment (pre-baking) was performed for 120 seconds using a hot plate at 100° C.

Next, using an i-ray stepper exposure device FPA-3000i5+ (manufactured by Canon Inc.), the film was irradiated with light having a wavelength of 365 nm through a 3.0 μm square island pattern mask with an exposure dose of 300 mJ/cm² (exposure dose required to obtain a line width of 3.0 μm).

Next, the silicon wafer on which the coating film after the exposure was formed was placed on a horizontal rotary table of a spin-shower developing machine (DW-30 Type, manufactured by Chemitronics Co., Ltd.), and subjected to a puddle development at 23° C. for 180 seconds using a developer (40% diluted solution of CD-2000 (manufactured by FUJIFILM Electronic Materials Co., Ltd.)) to form a pattern (pixel) on the silicon wafer. The silicon wafer on which the pattern (pixel) was formed was fixed on the horizontal rotary table by a vacuum chuck method, a rinse treatment was performed by supplying pure water from above a rotation center in shower-like while rotating the silicon wafer at a rotation speed of 50 rpm by a rotating device, and then the silicon wafer was spin-dried to form a pattern (pixel).

[Adhesiveness]

The produced pattern was observed using an optical microscope, and adhesiveness was evaluated according to the following standard.

AA: pattern was not peeled off.

A: pattern was peeled off in 1 to 5 pixels out of 100 pixels

B: pattern was peeled off in 6 to 15 pixels out of 100 pixels

C: pattern was peeled off in 16 or more pixels out of 100 pixels

[Residue]

The area (unexposed area) other than the pattern formation area was observed with a scanning electron microscope (SEM) (magnification: 10,000 times), the number of residues having a diameter of 0.1 μm or more per an area (one area) of 5 μm×5 μm of the unexposed area was counted, and the residue was evaluated according to the following evaluation standard.

AA: the number of residues per one area was less than 10.

A: the number of residues per one area was 10 or more and less than 20.

B: the number of residues per one area was 20 or more and less than 30.

C: the number of residues per one area was 30 or more.

[Rectangularity]

A cross section of the produced pattern was observed with a scanning electron microscope, the angle of a side wall of a 3.0 μm square pixel pattern formed with the optimum exposure dose with respect to a surface of the silicon wafer was measured, and rectangularity was evaluated according to the following evaluation standard.

AA: angle of the side wall of the pattern was 80° or more and less than 100°.

A: angle of the side wall of the pattern was 75° or more and less than 80°, or 100° or more and less than 105°.

B: angle of the side wall of the pattern was 70° or more and less than 75°, or 105° or more and less than 110°.

C: angle of the side wall of the pattern was less than 70°, or 110° or more.

TABLE 2

| | Evaluation result | | | |
|---|---|---|---|---|
| | Solvent | | | |
| | resistance | Adhesiveness | Residue | Rectangularity |
| Example 1 | AA | AA | AA | AA |
| Example 2 | AA | AA | AA | B |
| Example 3 | AA | AA | AA | A |
| Example 4 | AA | AA | A | AA |
| Example 5 | AA | AA | B | AA |
| Example 6 | AA | AA | AA | A |
| Example 7 | AA | AA | AA | AA |
| Example 8 | AA | AA | AA | AA |
| Example 9 | AA | AA | AA | AA |
| Example 10 | AA | AA | AA | AA |
| Example 11 | AA | AA | AA | AA |
| Example 12 | AA | AA | AA | AA |
| Example 13 | AA | A | AA | AA |
| Example 14 | AA | A | AA | A |
| Example 15 | B | A | A | A |
| Example 16 | A | B | A | B |
| Example 17 | A | B | A | B |
| Example 18 | A | A | B | A |
| Comparative | C | B | B | B |
| Example 1 | | | | |
| Comparative | B | C | C | C |
| Example 2 | | | | |
| Comparative | B | C | B | C |
| Example 3 | | | | |

As shown in the above table, Examples were excellent in solvent resistance, adhesiveness, residue, and rectangularity. On the other hand, in Comparative Examples including only one of the photopolymerization initiator A1 or the photopolymerization initiator A2, the evaluation of any of solvent resistance, adhesiveness, residue, or rectangularity was inferior to Examples.

What is claimed is:

1. A photosensitive coloring composition comprising:
a coloring material;
a photopolymerization initiator A1 having a light absorption coefficient of 1.0×10⁴ mL/g·cm or more at a wavelength of 365 nm in methanol;
a photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol; and
a polymerizable monomer,
wherein a content of the polymerizable monomer in a total solid content of the photosensitive coloring composition is 15% by mass or more.

2. The photosensitive coloring composition according to claim 1,
wherein the photopolymerization initiator A1 is an oxime compound including a fluorine atom.

3. The photosensitive coloring composition according to claim 1,
wherein the photopolymerization initiator A2 is a hydroxyalkylphenone compound.

4. The photosensitive coloring composition according to claim 1,
wherein the photopolymerization initiator A2 is a compound represented by Formula (A2-1), 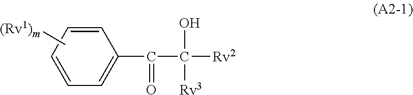
in the formula, Rv¹ represents a substituent, Rv² and Rv³ each independently represent a hydrogen atom or a substituent, Rv² and Rv³ may be bonded to each other to form a ring, and m represents an integer of 0 to 5.

5. The photosensitive coloring composition according to claim 1,
wherein the photosensitive coloring composition contains 50 to 200 parts by mass of the photopolymerization initiator A2 with respect to 100 parts by mass of the photopolymerization initiator A1.

6. The photosensitive coloring composition according to claim 1,
wherein a total content of the photopolymerization initiator A1 and the photopolymerization initiator A2 in the total solid content of the photosensitive coloring composition is 5% to 15% by mass.

7. The photosensitive coloring composition according to claim 1,
wherein the polymerizable monomer is a compound including three or more ethylenically unsaturated groups.

8. The photosensitive coloring composition according to claim 1,
wherein the polymerizable monomer is a compound including an ethylenically unsaturated group and an alkyleneoxy group.

9. The photosensitive coloring composition according to claim 1,
wherein the photosensitive coloring composition contains 170 to 345 parts by mass of the polymerizable monomer with respect to 100 parts by mass of a total amount of the photopolymerization initiator A1 and the photopolymerization initiator A2.

10. The photosensitive coloring composition according to claim 1,
wherein a content of the polymerizable monomer in the total solid content of the photosensitive coloring composition is 17.5% to 27.5% by mass.

11. The photosensitive coloring composition according to claim 1, further comprising:
a resin.

12. The photosensitive coloring composition according to claim 11,
wherein a content of the resin is 50 to 170 parts by mass with respect to 100 parts by mass of the polymerizable monomer.

13. A cured film obtained by curing the photosensitive coloring composition according to claim 1.

14. A method for forming a pattern, the method comprising:
forming a photosensitive coloring composition layer on a support using the photosensitive coloring composition according to claim 1;
irradiating the photosensitive coloring composition layer with a light having a wavelength of more than 350 nm and 380 nm or less to patternwise expose the photosensitive coloring composition layer;
developing the photosensitive coloring composition layer after the exposure; and
irradiating the photosensitive coloring composition layer after the development with a light having a wavelength of 254 to 350 nm to expose the photosensitive coloring composition layer after the development.

15. A color filter comprising:
the cured film according to claim 13.

16. A solid-state imaging element comprising:
the cured film according to claim 13.

17. An image display device comprising:
the cured film according to claim 13.
